(19) United States
(12) Patent Application Publication
(10) Pub. No.: US 2025/0201710 A1
(43) Pub. Date: Jun. 19, 2025

(54) SEMICONDUCTOR CHIP, METHOD OF MANUFACTURING THE SEMICONDUCTOR CHIP, AND SEMICONDUCTOR PACKAGE INCLUDING THE SEMICONDUCTOR CHIP

(71) Applicant: Samsung Electronics Co., Ltd., Suwon-si (KR)

(72) Inventors: Ilhwan KIM, Suwon-si (KR); Unbyoung KANG, Suwon-si (KR)

(73) Assignee: Samsung Electronics Co., Ltd., Suwon-si (KR)

(21) Appl. No.: 18/953,287

(22) Filed: Nov. 20, 2024

(30) Foreign Application Priority Data
Dec. 19, 2023 (KR) 10-2023-0186149

(51) Int. Cl. H01L 23/528; H01L 23/522

(52) U.S. Cl. CPC H01L 23/5283; H01L 23/5226

(57) ABSTRACT

A semiconductor chip includes a semiconductor substrate having a first surface and a second surface opposite to the first surface, an interconnect structure disposed on the second surface of the semiconductor substrate, a plurality of conductive patterns apart from the semiconductor substrate with the interconnect structure therebetween and each connected to the interconnect structure, a compensation pattern apart from the plurality of conductive patterns on the interconnect structure in a horizontal direction and farther from the second surface of the semiconductor substrate than the plurality of conductive patterns, and an insulating spacer placed between the plurality of conductive patterns and the compensation pattern.

### CROSS-REFERENCE TO RELATED APPLICATION

This application is based on and claims priority under 35 U.S.C. § 119 to Korean Patent Application No. 10-2023-0186149, filed on Dec. 19, 2023, in the Korean Intellectual Property Office, the disclosure of which is incorporated by reference herein in its entirety.

### BACKGROUND

The inventive concepts relate to a semiconductor chip, a method of manufacturing the semiconductor chip, and a semiconductor package including the semiconductor chip.

In accordance with the rapid development of the electronics industry and user demands, electronic devices have become smaller and lighter. Accordingly, a high degree of integration is required for semiconductor chips used in electronic devices, and design rules for components of semiconductor chips are further decreasing. A structure for improving the reliability of a thin semiconductor chip and a semiconductor package including the thin semiconductor chip has been proposed.

### SUMMARY

The inventive concepts provide a semiconductor chip having improved reliability.

The inventive concepts provide a method of manufacturing a semiconductor chip having improved reliability.

The inventive concepts provide a semiconductor package including a semiconductor chip having improved reliability.

According to an aspect of the inventive concepts, there is provided a semiconductor chip including a semiconductor substrate having a first surface and a second surface over and opposite to the first surface; an interconnect structure over the second surface of the semiconductor substrate; a plurality of conductive patterns spaced apart from the semiconductor substrate with the interconnect structure therebetween, the plurality of conductive patterns connected to the interconnect structure; a compensation pattern over the interconnect structure such that the compensation pattern is spaced apart from the plurality of conductive patterns in a horizontal direction and such that a distance from the compensation pattern to the second surface of the semiconductor substrate is greater than a distance from the plurality of conductive patterns to the second surface of the semiconductor substrate; and an insulating spacer between the plurality of conductive patterns and the compensation pattern.

According to an aspect of the inventive concepts, there is provided a semiconductor chip including a semiconductor substrate; an interconnect structure on an upper surface of the semiconductor substrate, the interconnect structure including a plurality of interconnection lines, a plurality of interconnection vias, and an interconnect insulating layer surrounding the plurality of interconnection lines and the plurality of interconnection vias; a plurality of conductive patterns over the interconnect structure, the plurality of conductive patterns spaced apart from each other in a horizontal direction and having thicknesses that are greater than those of the plurality of interconnect lines in a vertical direction; a compensation pattern over the interconnect structure, the compensation pattern spaced apart from the plurality of conductive patterns in the horizontal direction; an insulating spacer between the compensation pattern and the plurality of conductive patterns and between the interconnect structure and the compensation pattern; a frontside dielectric layer covering the plurality of conductive patterns, the compensation pattern, and the insulating spacer; and a plurality of frontside bonding pads passing through the frontside dielectric layer and the insulating spacer and respectively contacting the plurality of conductive patterns.

According to an aspect of the inventive concepts, there is provided a semiconductor package including a first semiconductor chip; and a second semiconductor chip bonded to the first semiconductor chip, wherein the first semiconductor chip comprises a first semiconductor substrate including a first surface and a second surface opposite to each other, a plurality of first backside bonding pads on the first surface of the first semiconductor substrate, and a first backside dielectric layer surrounding a sidewall of each of the plurality of first backside bonding pads on the first surface of the first semiconductor substrate, wherein the second semiconductor chip comprises a second semiconductor substrate including a first surface facing away from the semiconductor substrate and a second surface facing the first surface of the first semiconductor substrate, an interconnect structure on the second surface of the second semiconductor substrate, a frontside interconnect layer spaced apart from the second semiconductor substrate with the interconnect structure therebetween, a second frontside dielectric layer between the frontside interconnect layer and the first backside dielectric layer of the first semiconductor chip, such the second frontside dielectric layer of the second semiconductor chip is bonded to the first backside dielectric layer of the first semiconductor chip, and a plurality of second frontside bonding pads passing through the second frontside dielectric layer such that the plurality of second frontside bonding pads are bonded to the plurality of first backside bonding pads, wherein the frontside interconnect layer includes a plurality of conductive patterns spaced apart from each other in a horizontal direction and each including a first surface in contact with the interconnect structure and a second surface opposite to the first surface, a compensation pattern spaced apart from the plurality of conductive patterns in the horizontal direction and including a first surface facing the interconnect structure and a second surface opposite to the first surface, the second surface in contact with the second frontside dielectric layer, the compensation pattern being, and an insulating spacer between the plurality of conductive patterns and the compensation pattern and in contact with the second surface of each of the plurality of conductive patterns and the first surface of the compensation pattern, and wherein the plurality of second frontside bonding pads pass through the insulating spacer and contact the second surface of each of the plurality of conductive patterns.

According to an aspect of the inventive concepts, there is provided a method of manufacturing a semiconductor chip, the method including forming a plurality of conductive patterns on an interconnect structure such that the plurality of conductive patterns are apart from each other in a horizontal direction, the interconnect structure formed on a semiconductor substrate; forming a concave-convex structure including an insulating spacer that conformally covers the plurality of conductive patterns and the interconnect structure; forming a compensation material layer covering the concave-convex structure such that the compensation material layer covers the plurality of conductive patterns and the insulating spacer; forming a compensation pattern by planarizing the compensation material layer so that the insulating spacer is exposed; forming a frontside dielectric layer covering the insulating spacer and the compensation pattern; forming a plurality of first openings passing through the frontside dielectric layer and the insulating spacer to expose a plurality of conductive patterns; and forming a plurality of frontside bonding pads respectively filling the plurality of first openings.

### BRIEF DESCRIPTION OF THE DRAWINGS

Embodiments will be more clearly understood from the following detailed description taken in conjunction with the accompanying drawings in which:

FIG. 1 is a cross-sectional view showing a semiconductor chip according to embodiments;

FIG. 2 is an enlarged view of the area EXA1 in FIG. 1;

FIG. 3 is an enlarged view of the area EXA2 in FIG. 2;

FIGS. 4A, 4B, and 4C are plan views showing partial configurations of a semiconductor chip according to example embodiments;

FIG. 5A is a cross-sectional view showing a partial area of a semiconductor chip according to some other embodiments;

FIG. 5B is an enlarged view of the area EXB1 in FIG. 5A;

FIG. 6 is a cross-sectional view showing a partial area of a semiconductor chip according to some other embodiments;

FIG. 7 is a cross-sectional view showing a partial area of a semiconductor chip according to some other embodiments;

FIG. 8A is a cross-sectional view showing a partial area of a semiconductor chip according to some other embodiments;

FIG. 8B is a plan view showing a partial configuration of a semiconductor chip according to some other embodiments;

FIGS. 9A to 9F are cross-sectional views shown according to a process sequence to explain a method of manufacturing a semiconductor chip according to example embodiments;

FIGS. 10A to 10C are cross-sectional views shown according to a process sequence to explain a method of manufacturing a semiconductor chip according to some other embodiments;

FIG. 11 is a cross-sectional view illustrating a method of manufacturing the semiconductor chip according to some other embodiments;

FIGS. 12A to 12E are cross-sectional views shown according to a process sequent to explain a method of manufacturing a semiconductor chip according to some other embodiments;

FIG. 13 is a cross-sectional view showing a semiconductor package according to example embodiments;

FIG. 14 is an enlarged view of the area EXC1 in FIG. 11; and

FIG. 15 is a cross-sectional view showing a semiconductor package according to example embodiments.

### DETAILED DESCRIPTION OF THE EMBODIMENTS

Hereinafter, embodiments of the inventive concepts will be described in detail with reference to the accompanying drawings. The same reference numerals are used for the same components in the drawings, and duplicate descriptions thereof are omitted.

Hereinafter, example embodiments will be described in detail with reference to the accompanying drawings, wherein the sizes of components in the drawings may be exaggerated for clarity and convenience of explanation. Additionally, when the terms “about” or “substantially” are used in this specification in connection with a numerical value and/or a geometric term, it is intended that the associated numerical value and/or geometric term includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., ±10%) around the stated numerical values and/or geometry.

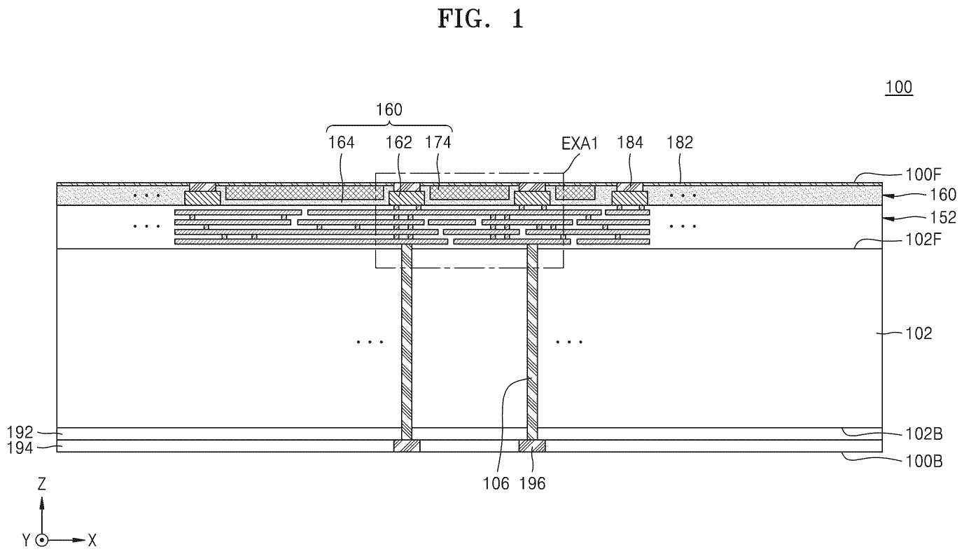

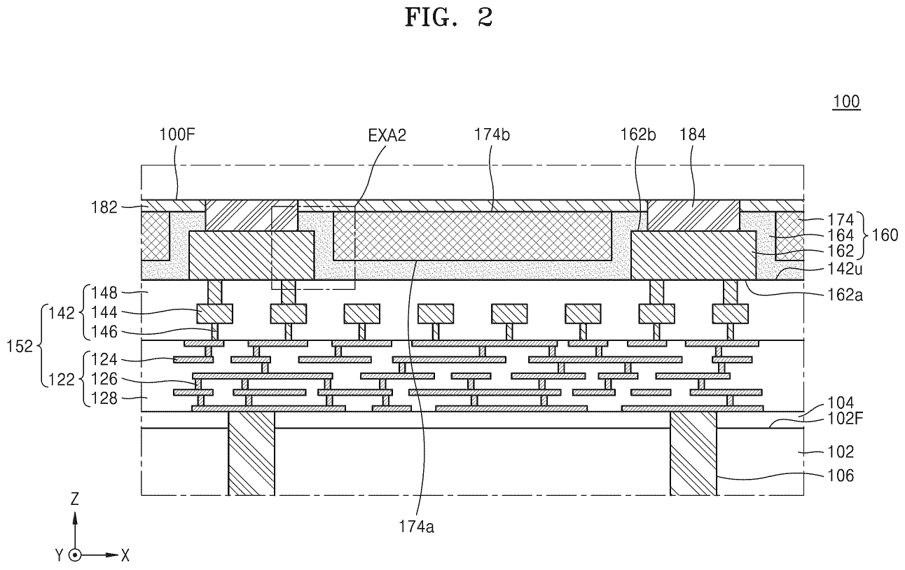

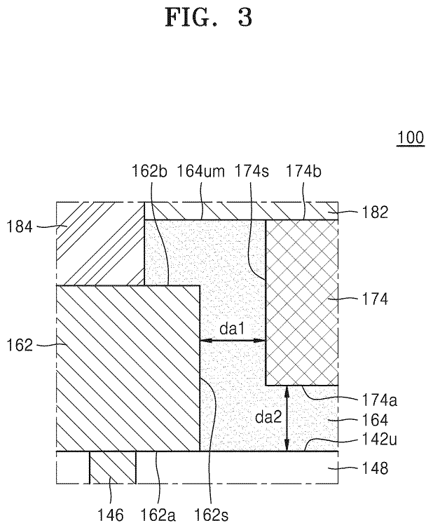

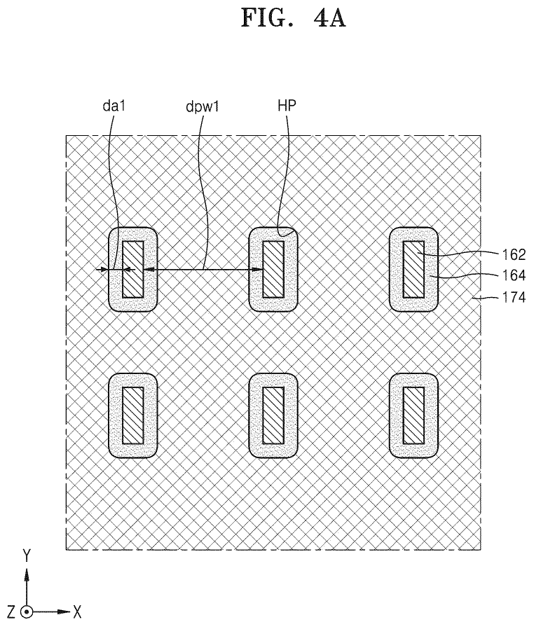

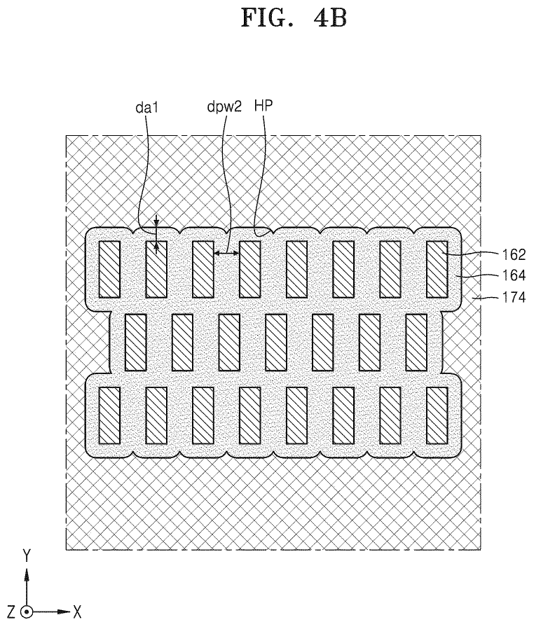

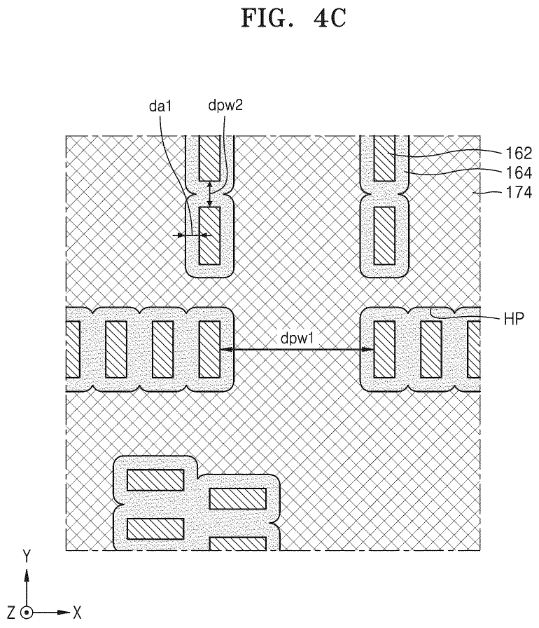

FIG. 1 is a cross-sectional view showing a semiconductor chip 100 according to embodiments. FIG. 2 is an enlarged view of the area EXA1 in FIG. 1. FIG. 3 is an enlarged view of the area EXA2 in FIG. 2. FIGS. 4A, 4B, and 4C are plan views showing partial configurations of the semiconductor chip 100 according to example embodiments.

Referring to FIGS. 1 to 4C, the semiconductor chip 100 may include a semiconductor substrate 102, an interconnect structure 152, a frontside interconnect layer 160, a frontside dielectric layer 182 (e.g., a frontside insulating layer), and a plurality of frontside bonding pads 184. According to example embodiments, the frontside interconnect layer 160 may include a plurality of conductive patterns 162, an insulating spacer 164, and a compensation pattern 174.

The semiconductor substrate 102 may include a first surface 102B and a second surface 102F that are opposite to each other. The first surface 102B of the semiconductor substrate 102 may be an inactive surface of the semiconductor substrate 102, and the second surface 102F of the semiconductor substrate 102 may be an active surface of the semiconductor substrate 102. Therefor, the first surface 102B of the semiconductor substrate 102 may also be referred to as the backside surface of the semiconductor substrate 102, and the second surface 102F of the semiconductor substrate 102 may also be referred to as the frontside surface of the semiconductor substrate 102.

Hereinafter, a direction parallel to the first surface 102B of the semiconductor substrate 102 is defined as a horizontal direction (an X direction and/or a Y direction), and a direction perpendicular to the first surface 102B of the semiconductor substrate 102 is defined as a vertical direction (a Z direction). In addition, a horizontal width refers to a length in the horizontal direction (the X direction and/or the Y direction), a vertical height refers to a length in the vertical direction (the Z direction), and a vertical level refers to a distance in the Z direction or −Z direction from the first surface 102B of the semiconductor substrate 102. However, such spatially relative terms are intended to encompass different orientations of the device in use or operation in addition to the orientation depicted in the figures. More specifically, such spatially relative terms, including “horizontal”, “vertical”, “over,” “under” and the like, will be understood as encompassing different orientations of the device in use or in operation such that the device may be otherwise oriented (for example, rotated 90 degrees or at other orientations) and the spatially relative descriptors used herein should be interpreted accordingly.

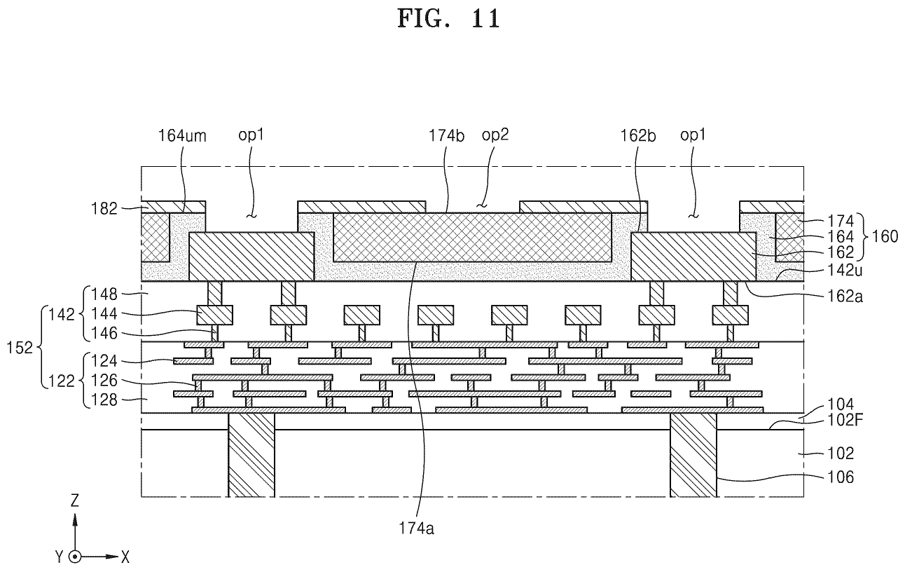

For example, unless otherwise specified in the present specification, an upper surface refers to a surface facing upward in the drawings, and a lower surface refers to a surface facing downward in the drawings. For example, in FIGS. 1 to 3, the first surface 102B of the semiconductor substrate 102 is disposed to face downward and the second surface 102F of the semiconductor substrate 102 is disposed to face upward. In this case, the first surface 102B, for example, the inactive surface of the semiconductor substrate 102, may be referred to as the lower surface of the semiconductor substrate 102. The second surface 102F, for example, the active surface of the semiconductor substrate 102, may be referred to as the upper surface of the semiconductor substrate 102. In contrast, in a semiconductor package 1000 described below with reference to FIGS. 11 to 13, semiconductor substrates 202 and 302 of a plurality of semiconductor chips 200 and 300 may each have a face down arrangement with an active surface facing downward. In this case, the active surface may be referred to as the lower surface of each of the semiconductor substrates 202 and 302.

The semiconductor substrate 102 may be formed from a semiconductor wafer. The semiconductor substrate 102 may include, for example, a semiconductor element, such as germanium (Ge) and/or silicon (Si), and/or a compound semiconductor, such as silicon carbide (SiC), gallium arsenide (GaAs), indium arsenide (InAs), and indium phosphide (InP). The semiconductor substrate 102 may include a conductive region, for example, a well doped with an impurity and/or a structure doped with an impurity. In addition, the semiconductor substrate 102 may have various semiconductor devices formed on the second surface 102F and a device isolation structure, such as a shallow trench isolation (STI) structure.

The various semiconductor devices (not shown) may include memory devices, logic devices, and/or components thereof. The memory devices may include, for example, Dynamic Random Access Memory (DRAM), Static Random Access Memory (SRAM), flash memory, Electrically Erasable and Programmable Read-Only Memory (EEPROM), Phase-change Random Access Memory (PRAM), Magnetic Random Access Memory (MRAM) Resistive Random Access Memory (RRAM) devices, and/or the like. The logic devices may include, for example, an AND gate, a NAND gate, an OR gate, a NOR gate, an exclusive OR (XOR) gate, an exclusive NOR (XNOR) gate, an inverter (INV), an adder (ADD), a delay (DLY), a filter (FIL), a multiplexer (MXT/MXIT), an OR/AND/INVERTER (OAI), an AND/OR (AO), an AND/OR/INVERTER (AOI), a D flip-flop, a reset flip-flop, a master-slave flip-flop, a latch, a counter, a buffer device, and/or the like. In addition, the logic devices may include a Central Processing Unit (CPU), a Micro-Processor Unit (MPU), a Graphics Processing Unit (GPU), an Application Processor (AP), and/or the like.

In some embodiments, the second surface 102F may be covered by an interlayer insulating layer 104. For example, the interlayer insulating layer 104 may surround a plurality of semiconductor devices (not shown) formed on the second surface 102F of the semiconductor substrate 102 and may insulate and/or protect the plurality of semiconductor devices (not shown) from each other. The interlayer insulating layer 104 may include an electrically insulating material. For example, in some embodiments, the interlayer insulating layer 104 may include a silicon oxide layer, a silicon nitride layer, and/or a combination thereof, but is not limited thereto. In the present specification, a layer including the plurality of semiconductor devices (not shown) and the interlayer insulating layer 104 surrounding the plurality of semiconductor devices may be referred to as a semiconductor device layer.

According to some example embodiments, the interconnect structure 152 and the frontside interconnect layer 160 may be sequentially disposed on the interlayer insulating layer 104. The interconnect structure 152 may be disposed on the second surface 102F of the semiconductor substrate 102. For example, the interconnect structure 152 may be disposed on the second surface 102F of the semiconductor substrate 102 and be spaced apart from the semiconductor substrate 102 with the interlayer insulating layer 104 therebetween. Although not shown in the drawings, the plurality of semiconductor devices (not shown) may be connected to the interconnect structure 152 through a contact (not shown) passing through the interlayer insulating layer 104.

According to some example embodiments, the interconnect structure 152 may include a first interconnect layer 122 and a second interconnect layer 142 sequentially stacked on the second surface 102F of the semiconductor substrate 102.

In some embodiments, the first interconnect layer 122 may include a plurality of conductive structures, including a plurality of first interconnect lines 124, a plurality of first interconnect vias 126, and a first interconnect insulating layer 128. The plurality of first interconnect lines 124 and the plurality of first interconnect vias 126 may be surrounded by the first interconnect insulating layer 128. The plurality of first interconnect lines 124 may include first interconnect lines 124 spaced apart from each other in the vertical direction (the Z direction) within the first interconnect insulating layer 128 and may each extend in the horizontal direction (the X direction and/or the Y direction). For example, the plurality of first interconnect lines 124 may be arranged at different vertical levels to form a multi-layer interconnect structure. The plurality of first interconnect vias 126 may extend between the plurality of first interconnect lines 124 arranged at different vertical levels and electrically connect a plurality of interconnect lines located at different vertical levels.

In some embodiments, the second interconnect layer 142 may include a second interconnect line 144, a plurality of second interconnect vias 146, and a second interconnect insulating layer 148 surrounding the second interconnect line 144 and the plurality of second interconnect vias 146. In some embodiments, the second interconnect line 144 may extend in the horizontal direction (at least one of the X direction and/or the Y direction). In some embodiments, the second interconnect line 144 may not only have a line shape but may also include a dot-shaped pad structure. The plurality of second interconnect vias 146 may extend in the vertical direction (the Z direction) within the second interconnect insulating layer 148. Some of the plurality of second interconnect vias 146 may connect the plurality of first interconnect lines 124 to the second interconnect line 144, and some others of the plurality of second interconnect vias 146 may connect the plurality of conductive patterns 162 to the second interconnect line 144.

In FIG. 2, the semiconductor chip 100 is illustrated as including five layers of the first interconnect lines 124 arranged at different vertical levels, but the examples are not limited thereto. For example, the semiconductor chip 100 may include 1 to 4, and/or 6 or more layers of the first interconnect lines 124. In FIG. 2, the semiconductor chip 100 is illustrated as including one second interconnect line 144, but is not limited thereto. For example, the semiconductor chip 100 may include a plurality of second interconnect lines 144 apart from each other in the vertical direction (the Z direction) within the second interconnect insulating layer 148. In these cases, the plurality of second interconnect vias 146 may connect, within the second interconnect insulating layer 148, the plurality of second interconnect lines 144 to each other, the lowermost second interconnect line 144 to the uppermost first interconnect line 124, and the uppermost second interconnect line 144 to the plurality of conductive patterns 162.

In some embodiments, the plurality of first interconnect lines 124, the plurality of first interconnect vias 126, the second interconnect line 144, and the plurality of second interconnect vias 146 may each include a metallically conductive material, such as a metal (e.g., copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), or an alloy thereof, and/or the like).

In some embodiments, the plurality of first interconnect lines 124 and the plurality of first interconnect vias 126 in the first interconnect layer 122 may include a different material from the second interconnect line 144 and the plurality of second interconnect vias 146 in the second interconnect layer 142. In some other embodiments, the plurality of first interconnect lines 124 and the plurality of first interconnect vias 126 in the first interconnect layer 122 may include the same material as the second interconnect line 144 and the plurality of second interconnect vias 146 in the second interconnect layer 142.

In some embodiments, the second interconnect line 144 of the second interconnect layer 142 may have a vertical thickness that is greater than those of the first interconnect lines 124 of the first interconnect layer 122, and the second interconnect vias 146 of the second interconnect layer 142 may have horizontal widths that are greater than those of the first interconnect vias 126 of the first interconnect layer 122.

In some embodiments, the first interconnect insulating layer 128 and the second interconnect insulating layer 148 may each include an electrically insulating oxide layer, such as tetraethyl orthosilicate (TEOS), phosphor silicate glass (PSG), boro-phosphor silicate glass (BPSG), undoped silicate glass (USG), plasma enhanced-TEOS (PE-TEOS), or a high density plasma-chemical vapor deposition (HDP-CVD) layer, a carbon-containing oxide layer, such as an SiOC or SiCOH layer, a silicon nitride layer, a carbon-containing nitride layer, a combination thereof, and/or the like.

According to some example embodiments, the frontside interconnect layer 160 may be disposed on an upper surface 142u of the second interconnect layer 142, and the frontside dielectric layer 182 may be disposed on the frontside interconnect layer 160. For example, the frontside interconnect layer 160 may be spaced apart from the semiconductor substrate 102 with the interconnect structure 152 therebetween. In some embodiments, the upper surface 142u of the second interconnect layer 142 may be parallel to the second surface 102F of the semiconductor substrate 102. For example, the upper surface 142u of the second interconnect layer 142 may extend flatly (and/or substantially flatly) in the horizontal direction (the X direction and/or the Y direction).

According to some example embodiments, the plurality of conductive patterns 162 may be arranged to be apart from each other on the upper surface 142u of the second interconnect layer 142. Each of the plurality of conductive patterns 162 may have a first surface 162a facing the semiconductor substrate 102 and a second surface 162b facing away from the semiconductor substrate 102. The plurality of conductive patterns 162 may be in contact with the upper surface 142u of the second interconnect layer 142. For example, the first surface 162a of each of the plurality of conductive patterns 162 may be in contact with some of the plurality of second interconnect vias 146 exposed at the upper surface 142u of the second interconnect layer 142, and the plurality of conductive patterns 162 may be electrically connected to the interconnect lines 124 and 144 and the interconnect vias 126 and 146 in the interconnect structure 152. The first surface 162a of each of the plurality of conductive patterns 162 may include a portion in contact with the second interconnect insulating layer 148. In FIGS. 1 to 3, the first surface 162a may be referred to as the lower surface of each of the plurality of conductive patterns 162, and the second surface 162b may be referred to as the upper surface of each of the plurality of conductive patterns 162.

According to some example embodiments, the insulating spacer 164 may cover the plurality of conductive patterns 162 and the upper surface 142u of the second interconnect layer 142. In some embodiments, the insulating spacer 164 may be in contact with portions of the second surface 162b of each of the plurality of conductive patterns 162, sidewalls 162s of each of the plurality of conductive patterns 162, and the upper surface 142u of the second interconnect layer 142. In some embodiments, the insulating spacer 164 may include a portion placed between the frontside dielectric layer 182 and the plurality of conductive patterns 162. For example, the second surface 162b of each of the plurality of conductive patterns 162 may include a portion that faces the frontside dielectric layer 182 with the insulating spacer 164 therebetween and another portion not vertically overlapping with the insulating spacer 164.

According to some example embodiments, the compensation pattern 174 may be disposed on the insulating spacer 164 and spaced apart from the plurality of conductive patterns 162 in the horizontal direction (the X direction and/or the Y direction). The insulating spacer 164 may be disposed between the plurality of conductive patterns 162 and the compensation pattern 174.

The compensation pattern 174 may have a first surface 174a facing the semiconductor substrate 102 and a second surface 174b facing away from the semiconductor substrate 102. According to some example embodiments, the first surface 174a and at least one of the sidewalls 174s of the compensation pattern 174 may be in contact with the insulating spacer 164. The compensation pattern 174 may face the upper surface 142u of the second interconnect layer 142 with the insulating spacer 164 therebetween. For example, the insulating spacer 164 may include a portion placed between the compensation pattern 174 and the interconnect structure 152.

According to some example embodiments, the plurality of conductive patterns 162 may be disposed closer to the semiconductor substrate 102 than the compensation pattern 174. In some embodiments, the first surface 174a of the compensation pattern 174 may be higher than the first surface 162a of each of the plurality of conductive patterns 162 and may be at a lower vertical level than the second surface 162b of each of the plurality of conductive patterns 162. For example, a distance between the first surface 162a of each of the plurality of conductive patterns 162 and the second surface 102F of the semiconductor substrate 102 may be less than a distance between the first surface 174a of the compensation pattern 174 and the second surface 102F of the semiconductor substrate 102.

According to some example embodiments, the frontside dielectric layer 182 may be disposed on the frontside interconnect layer 160. The second surface 174b of the compensation pattern 174 and the uppermost surface 164um of the insulating spacer 164 may be covered by the frontside dielectric layer 182. For example, the uppermost surface 16um of the insulating spacer 164 may be the upper surface of a portion of the insulating spacer 164 that does not vertically overlap the compensation pattern 174. For example, the uppermost surface 164um of the insulating spacer 164 may be the upper surface of a portion of the insulating spacer 164 farthest from the second surface 102F of the semiconductor substrate 102.

In some embodiments, the second surface 174b of the compensation pattern 174 may be at a higher vertical level than the second surface 162b of each of the plurality of conductive patterns 162. For example, a distance between the second surface 162b of each of the plurality of conductive patterns 162 and the second surface 102F of the semiconductor substrate 102 may be less than a distance between the second surface 174b of the compensation pattern 174 and the second surface 102F of the semiconductor substrate 102.

According to example embodiments, the sidewall 174s of the compensation pattern 174 may face the sidewall 162s of each of the plurality of conductive patterns 162 with the insulating spacer 164 therebetween. According to example embodiments, the sidewall 162s of each of the plurality of conductive patterns 162 may be spaced apart from the sidewall 174s of the compensation pattern 174 by a first separation distance da1 in the horizontal direction (the X direction and/or the Y direction). In some embodiments, a first conductive pattern 162 and a second conductive pattern 162, which are selected from among the plurality of conductive patterns 162 and are apart from each other with the compensation pattern 174 therebetween, may each be spaced apart from the compensation pattern 174 by the first separation distance da1. In some embodiments, portions of the sidewalls 162s of the plurality of conductive patterns 162, the portions facing the compensation pattern 174, may all have the same first separation distance da1.

According to some example embodiments, the first surface 174a of the compensation pattern 174 may be some apart from the interconnect structure 152 in the vertical direction (the Z direction) by a second separation distance da2 with the insulating spacer 164 therebetween. In some embodiments, the second separation distance da2 may be substantially equal to (and/or substantially similar to) the first separation distance da1.

In some embodiments, the distance between the second surface 162b of each of the plurality of conductive patterns 162 and the frontside dielectric layer 182 in the vertical direction (the Z direction) may be substantially equal to (and/or substantially similar to) the second separation distance da2. In some other embodiments, the distance between the second surface 162b of each of the plurality of conductive patterns 162 and the frontside dielectric layer 182 in the vertical direction (the Z direction) may be different from the second separation distance da2. For example, the distance between the second surface 162b of each of the plurality of conductive patterns 162 and the frontside dielectric layer 182 in the vertical direction (the Z direction) may be less than the distance between the first surface 174a of the compensation pattern 174 and the interconnect structure 152 in the vertical direction (the Z direction).

Referring to FIGS. 1 to 3, the vertical cross-sections of the plurality of conductive patterns 162 and the compensation pattern 174 are each illustrated as having a rectangular shape, but the example embodiments of the inventive concepts are not limited thereto. For example, in some embodiments, the horizontal width of each of the plurality of conductive patterns 162 may increase towards the second surface 102F of the semiconductor substrate 102 such that the vertical cross-section of each of the plurality of conductive patterns 162 may have a trapezoidal shape. For example, the sidewall 162s of each of the plurality of conductive patterns 162 may have an inclination with respect to the second surface 102F of the semiconductor substrate 102 and the vertical direction (the Z direction). In this case, the sidewall 174s of the compensation pattern 174 may have an inclination with respect to the second surface 102F of the semiconductor substrate 102 and the vertical direction (the Z direction) to correspond to the sidewall 162s of each of the plurality of conductive patterns 162. For example, the horizontal width of a portion of the compensation pattern 174 placed between two adjacent conductive patterns 162 may decrease towards the second surface 102F of the semiconductor substrate 102.

FIGS. 4A, 4B, and 4C illustrate the planar arrangement relationship between the plurality of conductive patterns 162, the compensation pattern 174, and the insulating spacer 164 in the frontside interconnect layer 160. According to some example embodiments, the compensation pattern 174 may have a plurality of holes HP that accommodate the plurality of conductive patterns 162. The inner wall/inner boundary of each of the plurality of holes HP is composed of the sidewall 174s of the compensation pattern 174. At least one conductive pattern 162 may be disposed in each of the plurality of holes HP. In a plan view, the compensation pattern 174 may be arranged to surround the plurality of conductive patterns 162. According to some example embodiments, the compensation pattern 174 may fill an area in the frontside interconnect layer 160 where the plurality of conductive patterns 162 are not disposed, and accordingly, deviation in pattern density depending on the area of the frontside interconnect layer 160 may be reduced.

Referring to FIG. 4A, a first group of conductive patterns 162 among the plurality of conductive patterns 162 may be disposed one by one in each of the plurality of holes HP. The first group of conductive patterns 162 may be arranged to be apart from each other in the horizontal direction (the X direction and/or the Y direction) with the compensation pattern 174 therebetween and may each be surrounded by the insulating spacer 164. For example, the compensation pattern 174 may be disposed between each two of the first group of conductive patterns 162. In some embodiments, the first group of conductive patterns 162 may each be apart from the inner boundary of a corresponding hole HP among the plurality of holes HP by the first separation distance da1 in a plan view. For example, in a plan view, each of the first group of conductive patterns 162 may have an independent island shape. In some embodiments, a first pattern interval dpw1, which is a distance between two conductive patterns 162 selected from the first group of conductive patterns 162 and disposed adjacent to each other, may be greater than twice the first separation distance da1. For example, the first pattern interval dpw1 may be a horizontal distance between two conductive patterns 162 arranged adjacent to each other with the compensation pattern 174 therebetween.

Referring to FIG. 4B, a second group of conductive patterns 162 among the plurality of conductive patterns 162 may be disposed in a single hole HP. The second group of conductive patterns 162 may be arranged to be relatively dense with each other compared to the first group of conductive patterns 162 described with reference to FIG. 4A. In some embodiments, two adjacent conductive patterns 162 among the second group of conductive patterns 162 may have a second pattern interval dpw2 that is less than the first pattern interval dpw1. For example, the second pattern interval dpw2 may be less than twice the first separation distance da1. For example, the second pattern interval dpw2 may be a horizontal distance between two conductive patterns 162 arranged adjacent to each other with the insulating spacer 164 therebetween.

In some embodiments, the compensation pattern 174 may not be disposed between two adjacent conductive patterns 162 among the second group of conductive patterns 162, and the two conductive patterns 162 may be apart from each other with the insulating spacer 164 therebetween. The first conductive pattern 162 selected from among the second group of conductive patterns 162 may be disposed on the center side of the second group of conductive patterns 162 and may be surrounded by other adjacent conductive patterns 162. In these cases, the distance between the sidewall 162s of the first conductive pattern 162 and the sidewall 174s of the compensation pattern 174 may be greater than the first separation distance da1. In some embodiments, the sidewall 162s of each of the conductive patterns 162 disposed on the outside from among the second group of conductive patterns 162 that are densely arranged may include a portion facing the sidewall 174s of the compensation pattern 174. In these cases, the sidewall 162s of each of the conductive patterns 162 may be apart from the compensation pattern 174 by the first separation distance da1. Therefore, in at least some of these cases, the second pattern interval dpw2 may be less than twice the first separation distance da1 and greater than or equal to the first separation distance da1 (e.g., da1≤dpw2<(2*da1)).

Referring to FIG. 4C, the plurality of conductive patterns 162 may include a plurality of groups apart from each other in the horizontal direction (the X direction and/or the Y direction). In some embodiments, the plurality of groups may each be arranged in a corresponding hole HP among the plurality of holes HP, and the plurality of groups may be apart from each other with the compensation pattern 174 therebetween. In some embodiments, conductive patterns 162 of some of the plurality of groups may be arranged in a row in one horizontal direction. In some embodiments, conductive patterns 162 of some other of the plurality of groups may be arranged in a zigzag pattern in one horizontal direction. Within each hole HP, conductive patterns 162 constituting each group may be apart from each other by the second pattern interval dpw2. The plurality of groups are each disposed in one hole HP, but unlike the conductive patterns 162 of FIG. 4B, the conductive patterns 162 constituting each group may all have sidewalls 162s facing the compensation pattern 174. In some embodiments, a third group of conductive patterns 162 and a fourth group of conductive patterns 162 selected from among the plurality of groups may be apart from each other with the compensation pattern 174 therebetween. A first conductive pattern 162, which is selected from the third group of conductive patterns 162 and adjacent to the fourth group of conductive patterns 162, may be apart from a second conductive pattern 162, which is selected from the fourth group of conductive patterns 162 and adjacent to the third group of conductive patterns 162, by the first pattern interval dwp1 with the compensation pattern 174 therebetween.

In FIGS. 4A to 4C, the plurality of conductive patterns 162 are illustrated as having rectangular pad shapes with different widths in the first horizontal direction (the X direction) and in the second horizontal direction (the Y direction), but are not limited thereto. For example, the plurality of conductive patterns 162 may each have a planar geometric shape, such as a square, a rhombus, a circle, and/or the like. In addition, unlike the illustrations in FIGS. 4A to 4C, the plurality of conductive patterns 162 may each have a line shape extending in the horizontal direction (the X direction and/or the Y direction). FIGS. 4A to 4C illustrate planar arrangement relationships between the plurality of conductive patterns 162, the insulating spacer 164, and the compensation pattern 174 according to example embodiments, but the example embodiments of the inventive concepts is not limited thereto and the planar arrangement relationships may be modified and changed in various ways by one of ordinary skill in the art within the technical spirit and scope of the inventive concepts.

In some embodiments, the plurality of conductive patterns 162 and the compensation pattern 174 may each include a metal, such as Cu, Al, W, Ti, Ta, In, Mo, Mn, Co, Sn, Ni, Mg, Re, Be, Ga, or Ru, or an alloy thereof.

In some embodiments, the plurality of conductive patterns 162 and the compensation pattern 174 may include the same material. In some other embodiments, the plurality of conductive patterns 162 and the compensation pattern 174 may include different materials. In some embodiments, the plurality of conductive patterns 162 may include the same material as the second interconnect line 144 of the second interconnect layer 142 and the plurality of second interconnect vias 146.

In some embodiments, the insulating spacer 164 may include an oxide layer, such as a TEOS, PSG, BPSG, USG, PE-TEOS, or an HDP-CVD layer, a carbon-containing oxide layer, such as an SiOC or SiCOH layer, a silicon nitride layer, a carbon-containing nitride layer, a combination thereof, and/or the like.

The interconnect structure 152 and the frontside interconnect layer 160 may form a back end of line (BEOL) structure provided on the second surface 102F of the semiconductor substrate 102. In some embodiments, the thicknesses of interconnect lines constituting the BEOL structure may increase as the distance from the second surface 102F of the semiconductor substrate 102 increases. In some embodiments, the thicknesses of the plurality of conductive patterns 162 in the vertical direction (the Z direction) may be greater than those of the plurality of first interconnect lines 124 and the second interconnect line 144. In some other embodiments, the vertical thicknesses of the plurality of conductive patterns 162 may be substantially equal to the vertical thickness of the second interconnect line 144 and may be greater than the vertical thicknesses of the plurality of first interconnect lines 124.

The semiconductor chip 100 according to the example embodiments may include the compensation pattern 174 placed between the plurality of conductive patterns 162 and may thus induce uniform pattern density for each area within the frontside interconnect layer 160. Accordingly, surface distortion of the front surface 100F of the semiconductor chip 100, which may occur when the plurality of conductive patterns 162 concentrate in only some areas in a planar view, may be reduced. The compensation pattern 174 according to some embodiments may include a material, such as metal having relatively high thermal conductivity, and thus, the heat dissipation characteristics of the semiconductor chip 100 may also be improved.

According to some example embodiments, the plurality of frontside bonding pads 184 may pass through the frontside dielectric layer 182 and the insulating spacer 164 and may each contact at least some of the plurality of conductive patterns 162. The plurality of frontside bonding pads 184 may be arranged to be apart from each other in the horizontal direction (the X direction and/or the Y direction) and may be exposed on the front surface 100F of the semiconductor chip 100. The plurality of frontside bonding pads 184 may be connected to the interconnect structure 152 through the plurality of conductive patterns 162.

In some embodiments, each of the plurality of frontside bonding pads 184 may be in contact with the second surface 162b of a corresponding conductive pattern 162 among the plurality of conductive patterns 162. In some embodiments, the sidewall of each of the plurality of frontside bonding pads 184 may include a portion in contact with the frontside dielectric layer 182 and a portion in contact with the insulating spacer 164. The insulating spacer 164 may cover a portion of the second surface 162b of each of the plurality of conductive patterns 162, the portion not being in contact with the plurality of frontside bonding pads 184. In some embodiments, the sidewall of each of the plurality of frontside bonding pads 184 may include a portion that faces the compensation pattern 174 with the insulating spacer 164 therebetween.

In some embodiments, the plurality of frontside bonding pads 184 may include a metallically conductive material such as chrome (Cr), tungsten (W), titanium (Ti), copper (Cu), nickel (Ni), aluminum (Al), palladium (Pd), gold (Au), a combination thereof, and/or the like. In some embodiments the metallically conductive material of the plurality of frontside bonding pads 184 may be selected based on bond compatibility with, e.g., a solder or direct bonding.

In some embodiments, the frontside dielectric layer 182 may include an electrically insulating material, such at least one of SiO, SiN, SiCN, SiCO, a polymer-based insulator material, and/or the like. For example, the polymer-based insulator material may be and/or include BCB, PI, PBO, silicone, and/or epoxy. In some embodiments, the frontside dielectric layer 182 may have a multi-layered structure including a plurality of insulating material layers stacked in the vertical direction (the Z direction).

Referring to FIG. 1, the semiconductor chip 100 may include a passivation layer 192 and a backside dielectric layer 194 (e.g., a backside insulating layer) sequentially stacked on the first surface 102B of the semiconductor substrate 102. The semiconductor chip 100 includes a plurality of through electrodes 106 passing through the semiconductor substrate 102 and the passivation layer 192 in the vertical direction (the Z direction), and a plurality of backside bonding pads 196 respectively in contact with the plurality of through electrodes 106 on the lower surface of the passivation layer 192 and surrounded by the backside dielectric layer 194. For example, the sidewall of each of the plurality of backside bonding pads 196 may be surrounded by the backside dielectric layer 194.

In some embodiments, the plurality of through electrodes 106 may each have a pillar shape extending through the semiconductor substrate 110, the interlayer insulating layer 104, and the passivation layer 192. In some embodiments, one end of each of the plurality of through electrodes 106 in the vertical direction (the Z direction) may pass through the interlayer insulating layer 104 and be in contact with and connected to the lowermost first interconnect line 124 among the plurality of first interconnect lines 124. The other ends of the plurality of through electrodes 106 in the vertical direction (the Z direction) may be respectively in contact with and connected to the plurality of backside bonding pads 196. The plurality of through electrodes 106 may form an electrical path between the plurality of backside bonding pads 196 and at least some of the various semiconductor devices (not shown) formed on the second surface 102F of the semiconductor substrate 102. The electrical path may be configured, for example, such that the various semiconductor devices (not shown) may communicate with and/or receive power from an external device (not shown) connected to plurality of backside bonding pads 196.

Although not shown in the drawings, the plurality of through electrodes 106 may each include a conductive plug extending in the vertical direction (the Z direction) and a conductive barrier layer disposed on the outer surface of the conductive plug. In some embodiments, the conductive plug may include a metallically conductive material, such as Cu, Ni, Au, Ag, W, Ti, Ta, In, Mo, Mn, Co, Sn, Mg, Re, Be, Ga, Ru, a combination thereof, and/or the like. In some embodiments, the conductive barrier layer may include Ti, titanium nitride (TiN), Ta, tantalum nitride (TaN), W, tungsten nitride (WN), Ru, Co, a combination thereof, and/or the like. In some embodiments, the semiconductor chip 100 may include a via insulating layer placed between the plurality of through electrodes 106 and the semiconductor substrate 102, between the plurality of through electrodes 106 and the interlayer insulating layer 104, and between the plurality of through electrodes 106 and the passivation layer 192. In some embodiments, the via insulating layer may include a high aspect ratio process (HARP) oxide based on ozone/tetra-ethyl ortho-silicate (O₃/TEOS), but is not limited thereto.

In some embodiments, the passivation layer 192 and the backside dielectric layer 194 may each include oxide and/or nitride. In some embodiments, the passivation layer 120 may include at least one of SiO, SiN, SiCN, SiCO, and a polymer material. For example, the polymer material may be and/or include benzocyclobutene (BCB), polyimide (PI), polybenzoxazole (PBO), silicone, and/or epoxy. For example, the passivation layer 192 and the backside dielectric layer 194 may each have a multi-layered structure including a plurality of insulating material layers stacked in the vertical direction (the Z direction).

In some embodiments, the plurality of backside bonding pads 196 may include a metallically conductive material such as Cr, W, Ti, Cu, Ni, Al, Pd, Au, a combination thereof, and/or the like. In some embodiments the metallically conductive material of the plurality of backside bonding pads 196 may be selected based on bond compatibility with, e.g., a solder or direct bonding.

According to example embodiments, the semiconductor chip 100 includes the frontside interconnect layer 160 disposed closest to the front surface 100F of the semiconductor chip 100 on the second surface 102F of the semiconductor substrate 102. In a plan view, an area in the frontside interconnect layer 160 where the plurality of conductive patterns 162 are not disposed is filled with the compensation pattern 174, and the compensation pattern 174 may be apart from the plurality of conductive patterns 162 through the insulating spacer 164. The first surface 162a of each of the plurality of conductive patterns 162 is in contact with the upper surface of the interconnect structure 152 (e.g., the upper surface 142u of the second interconnect layer 142), but the compensation pattern 174 is apart from the interconnect structure 152 with the insulating spacer 164 therebetween. The compensation pattern 174 and insulating spacer 164 may be formed to conformally cover the upper surface 142u of the second interconnect layer 142 and the plurality of conductive patterns 162 after the plurality of conductive patterns 162 are formed, and thus, the first separation distance da1 between the compensation pattern 174 and the plurality of conductive patterns 162 may be adjusted with low process difficulty.

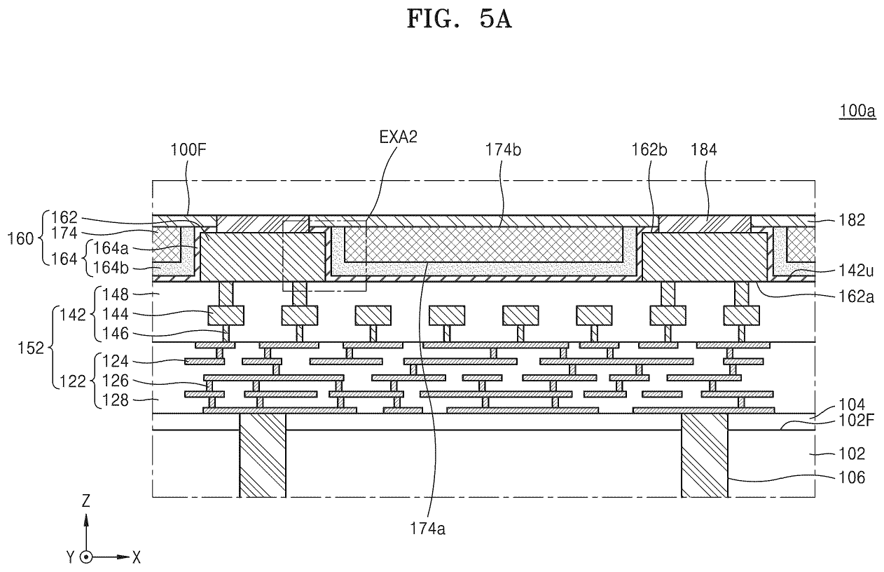

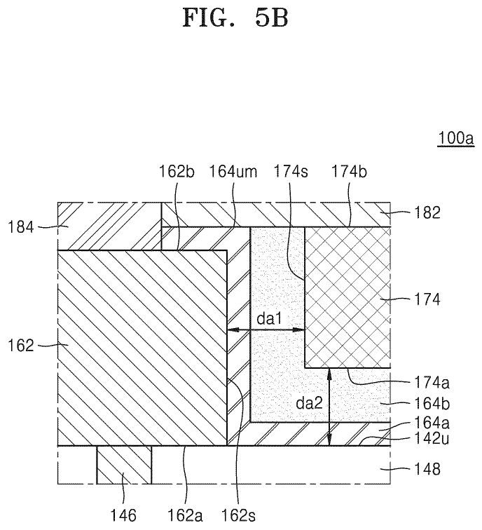

FIG. 5A is a cross-sectional view showing a partial area of a semiconductor chip 100a according to some other embodiments. Specifically, FIG. 5A shows an area corresponding to the area EXA1 in FIG. 1. FIG. 5B is an enlarged view of the area EXB1 in FIG. 5A. In FIGS. 5A and 5B, the same reference numerals as in FIGS. 1 to 4C indicate the same members, and duplicate descriptions thereof are omitted here.

Referring to FIGS. 5A and 5B, the insulating spacer 164 may include a first spacer layer 164a and a second spacer layer 164b sequentially stacked on the upper surface of the interconnect structure 152 (e.g., the upper surface 142u of the second interconnect layer 142).

According to some example embodiments, the first spacer layer 164a may cover and be in contact with the upper surface 142u of the second interconnect layer 142, the sidewall 162s of each of the plurality of conductive patterns 162, and a portion of the second surface 162b of each of the plurality of conductive patterns 162. According to some example embodiments, the second spacer layer 164b may cover and be in contact with the first surface 174a and the sidewall 174s of the compensation pattern 174 on the first spacer layer 164a but may not cover the second surface 162b of each of the plurality of conductive patterns 162. For example, according to some example embodiments, the second spacer layer 164b may not vertically overlap the second surface 162b of each of the plurality of conductive patterns 162.

In some embodiments, the second spacer layer 164b may be spaced apart from the plurality of conductive patterns 162 in the horizontal direction (the X direction and/or the Y direction). In some embodiments, the second surface 162b of each of the plurality of conductive patterns 162 may be spaced apart from the frontside dielectric layer 182 with the first spacer layer 164a therebetween. In some embodiments, the first spacer layer 164a and the second spacer layer 164b may be placed between the sidewall 162s of each of the plurality of conductive patterns 162 and the sidewall 174s of the compensation pattern 174. In some embodiments, the first separation distance da1 may be the sum of the thickness of the first spacer layer 164a and the thickness of the second spacer layer 164b.

In some embodiments, the first spacer layer 164a and the second spacer layer 164b may be placed between the compensation pattern 174 and the interconnect structure 152. For example, the second separation distance da2 may be the sum of the thickness of the first spacer layer 164a and the thickness of the second spacer layer 164b. In some embodiments, the distance between the second surface 162b of each of the plurality of conductive patterns 162 and the frontside dielectric layer 182 in the vertical direction (the Z direction) may be less than the second separation distance da2. In some embodiments, the distance between the second surface 162b of each of the plurality of conductive patterns 162 and the frontside dielectric layer 182 in the vertical direction (the Z direction) may be substantially equal to the thickness of the first spacer layer 164a.

In some embodiments, the uppermost surface of the first spacer layer 164a and the uppermost surface of the second spacer layer 164b may each be in contact with the frontside dielectric layer 182 and may constitute the uppermost surface 164um of the insulating spacer 164. In some embodiments, the uppermost surface of the first spacer layer 164a may be coplanar with the uppermost surface of the second spacer layer 164b.

In some embodiments, the sidewall of each of the plurality of frontside bonding pads 184 may be in contact with the first spacer layer 164a and the frontside dielectric layer 182 but may not be in contact with the second spacer layer 164b.

In FIGS. 5A and 5B, the thickness of the first spacer layer 164a is illustrated as being less than the thickness of the second spacer layer 164b, but the example embodiments are not limited thereto. In some embodiments, the thickness of the first spacer layer 164a may be equal to the thickness of the second spacer layer 164b or greater than the thickness of the second spacer layer 164b. In FIGS. 5A and 5B, the insulating spacer 164 is illustrated as including two spacer layers 164a and 164b, but the example embodiments of the inventive concepts are not limited thereto. For example, the insulating spacer 164 may include three or more spacer layers.

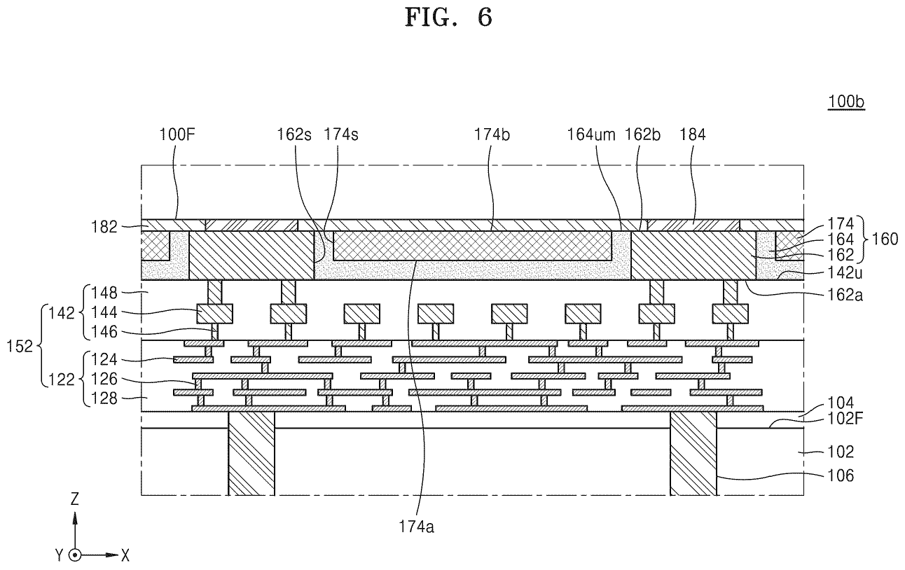

FIG. 6 is a cross-sectional view showing a partial area of a semiconductor chip 100b according to some other embodiments. Specifically, FIG. 6 shows an area corresponding to the area EXA1 in FIG. 1. In FIG. 6, the same reference numerals as in FIGS. 1 to 4C and FIGS. 5A and 5B indicate the same members, and duplicate descriptions thereof are omitted here.

Referring to FIG. 6, the insulating spacer 164 of the semiconductor chip 100b may cover the sidewall 162s of each of the plurality of conductive patterns 162 but does not cover the second surface 162b of each of the plurality of conductive patterns 162. According to some example embodiments, the plurality of frontside bonding pads 184 may pass through the frontside dielectric layer 182 and be in contact with the plurality of conductive patterns 162. In some embodiments, the sidewall of each of the plurality of frontside bonding pads 184 may be surrounded by the frontside dielectric layer 182. In some embodiments, a portion of the second surface 162b of each of the plurality of conductive patterns 162, the portion not being in contact with the plurality of frontside bonding pads 184, may be in contact with the frontside dielectric layer 182.

In some embodiments, the second surface 162b of each of the plurality of conductive patterns 162 and the second surface 174b of the compensation pattern 174 may be at the same vertical level (and/or substantially similar vertical levels). In some embodiments, the second surface 162b of each of the plurality of conductive patterns 162, the second surface 174b of the compensation pattern 174, and the uppermost surface 164um of the insulating spacer 164 may be coplanar. In some embodiments, the thickness of each of the plurality of conductive patterns 162 in the vertical direction (the Z direction) may be greater than the thickness of the compensation pattern 174 in the vertical direction (the Z direction). In some embodiments, the sidewall 174s of the compensation pattern 174 may face the plurality of conductive patterns 162 but may not face the plurality of frontside bonding pads 184.

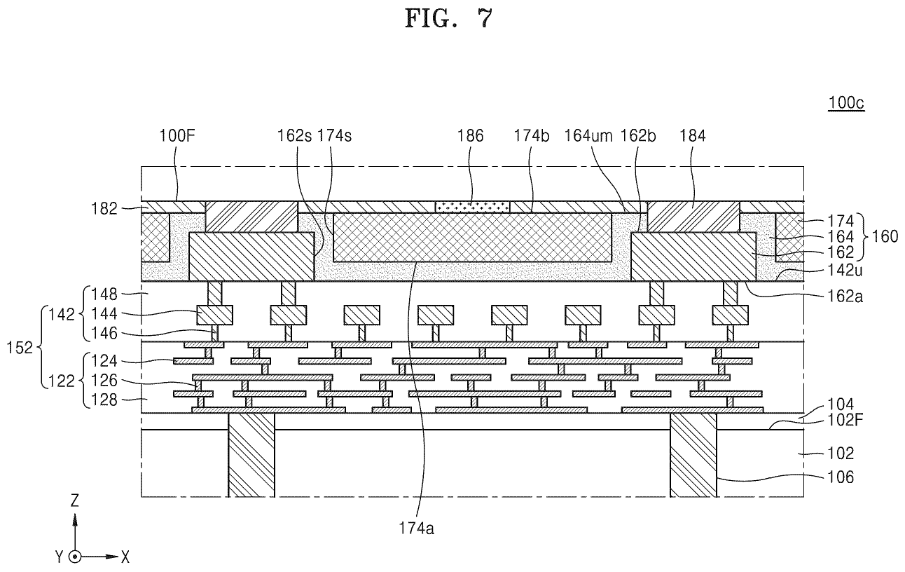

FIG. 7 is a cross-sectional view showing a partial area of a semiconductor chip 100c according to some other embodiments. Specifically, FIG. 7 shows an area corresponding to the area EXA1 in FIG. 1. In FIG. 7, the same reference numerals as in FIGS. 1 to 4C, 5A and 5B, and 6 indicate the same members, and duplicate descriptions thereof are omitted here.

Referring to FIG. 7, the semiconductor chip 100c may include a plurality of first frontside dummy pads 186 that pass through the frontside dielectric layer 182 and be in contact with the compensation pattern 174. For example, the plurality of first frontside dummy pads 186 may be in contact with the second surface 174b of the compensation pattern 174. In some embodiments, the plurality of first frontside dummy pads 186 may be exposed at the front surface 100F of the semiconductor chip 100c, and the upper surface of the plurality of first frontside dummy pads 186 may be exposed at the front surface 100F of the semiconductor chip 100c. It may be coplanar with the upper surface of the frontside bonding pad 184. In some embodiments, the plurality of first frontside dummy pads 186 may be apart from the plurality of frontside bonding pads 184 with the frontside dielectric layer 182 therebetween.

The plurality of first frontside dummy pads 186 may be disposed on the compensation pattern 174, which does not vertically overlap the plurality of frontside bonding pads 184, and reduce pattern density deviation for each area within the frontside dielectric layer 182. Although only one first frontside dummy pad 186 is illustrated in FIG. 7, the plurality of first frontside dummy pads 186 may be arranged to be apart from each other on the compensation pattern 174 extending in the horizontal direction (the X direction and/or the Y direction).

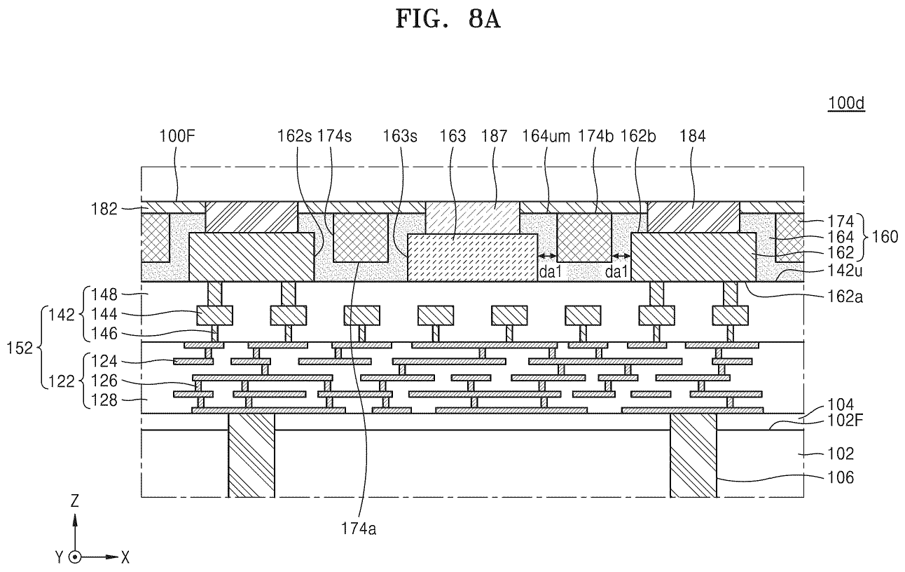

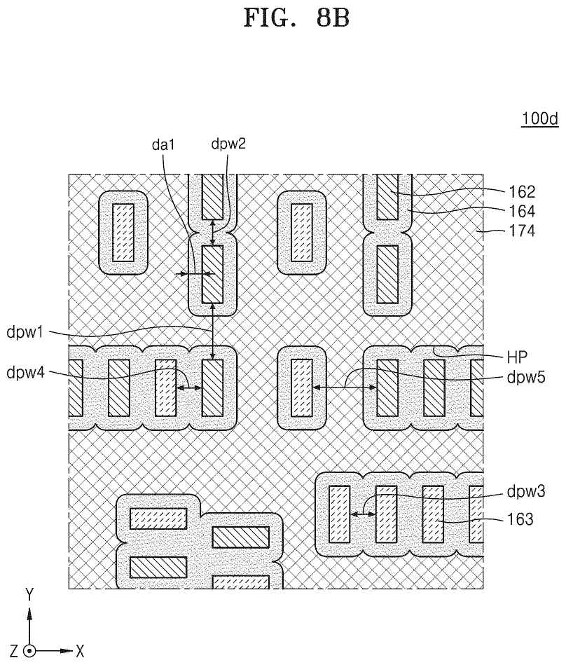

FIG. 8A is a cross-sectional view showing a partial area of a semiconductor chip 100d according to some other embodiments. Specifically, FIG. 8A shows an area corresponding to the area EXA1 in FIG. 1. FIG. 8B is a plan view showing a partial configuration of the semiconductor chip 100d according to some other embodiments. In FIGS. 8A and 8B, the same reference numerals as in FIGS. 1 to 7 indicate the same members, and duplicate descriptions thereof are omitted here.

Referring to FIGS. 8A and 8B, the semiconductor chip 100d may include a plurality of dummy patterns 163 and a plurality of second frontside dummy pads 187. According to example embodiments, the plurality of dummy patterns 163 and the plurality of second frontside dummy pads 187 may have substantially the same structure as the plurality of conductive patterns 162 and the plurality of frontside bonding pads 184 described with reference to FIGS. 1 to 7, respectively. However, the plurality of dummy patterns 163 may not be in contact with the plurality of second interconnect vias 146 and/or the second interconnect line 144 in the second interconnect layer 142. For example, the plurality of dummy patterns 163 may not be connected to conductive structures 124, 126, 144, and 146 constituting the interconnect structure 152. The plurality of dummy patterns 163 and the plurality of second frontside dummy pads 187 may not be electrically connected to the conductive structures 124, 126, 144, and 146 and may improve the topology characteristics of the front surface 100F of the semiconductor chip 100 by filling the areas where the plurality of conductive patterns 162 are not disposed, in a plan view.

For example, the plurality of dummy patterns 163 may be in contact with the upper surface 142u of the second interconnect layer 142 and may be apart from each other and from the plurality of conductive patterns 162. The plurality of dummy patterns 163 may be apart from the compensation pattern 174 with the insulating spacer 164 therebetween. The insulating spacer 164 may include a portion placed between the plurality of dummy patterns 163 and the frontside dielectric layer 182. For example, the upper surface of each of the plurality of dummy patterns 163 may be spaced apart from the frontside dielectric layer 182 with the insulating spacer 164 therebetween. The plurality of second frontside dummy pads 187 may individually contact the plurality of dummy patterns 163 by passing through the frontside dielectric layer 182 and the insulating spacer 164. The sidewall of each of the plurality of second frontside dummy pads 187 may include a portion facing the frontside dielectric layer 182 and a portion facing the compensation pattern 174. In some embodiments, the insulating spacer 164 may include a portion in contact with the sidewall 163s of each of the plurality of dummy patterns 163 and a portion in contact with the sidewall of each of the plurality of second frontside dummy pads 187.

Referring to FIG. 8B, in a plan view, the plurality of dummy patterns 163 may be surrounded by the insulating spacer 164 and may be surrounded by the compensation pattern 174 with the insulating spacer 164 therebetween. As illustrated in FIG. 8B, a first group of dummy patterns 163 selected from among the plurality of dummy patterns 163 may each be disposed within one hole HP and have an independent island shape. For example, each of the first group of dummy patterns 163 may be apart from the compensation pattern 174 by a first separation distance da1.

In some embodiments, a second group of dummy patterns 163 selected from among the plurality of dummy patterns 163 may be disposed within one hole HP and adjacent to each other. For example, two dummy patterns 163 selected from among the second group of dummy patterns 163 may be arranged to be apart from each other with the insulating spacer 164 therebetween. A third pattern interval dpw3, which is the distance between the two dummy patterns 163 selected from among the second group of dummy patterns 163 and arranged adjacent to each other, may be less than twice the first separation distance da1. Therefore, in at least some of these cases, the third pattern interval dpw3 may be less than twice the first separation distance da1 and greater than or equal to the first separation distance da1 (e.g., da1≤dpw3<(2*da1)).

In some embodiments, the third group of dummy patterns 163 selected from among the plurality of dummy patterns 163 may be disposed within one hole HP and adjacent to some of the conductive patterns 162. For example, the third group of dummy patterns 163 may each be apart from an adjacent conductive pattern 162 or another dummy pattern 163 with the insulating spacer 164 therebetween. For example, a fourth pattern interval dpw4, which is the distance between one selected from the third group of dummy patterns 163 and an adjacent conductive pattern 162, may be less than twice the first separation distance da1. Therefore, in at least some of these cases, the fourth pattern interval dpw4 may be less than twice the first separation distance da1 and greater than or equal to the first separation distance da1 (e.g., da1≤dpw4<(2*da1)).

In some embodiments, some of the plurality of dummy patterns 163 may be apart from some others of the plurality of dummy patterns 163 or the conductive pattern 162 with the compensation pattern 174 therebetween. For example, a first dummy pattern 163 selected from the plurality of dummy patterns 163 and disposed in a first hole HP among the plurality of holes HP may be apart from another dummy pattern 163 or the conductive pattern 162 by a fifth pattern interval dpw5, the other dummy pattern 163 or the conductive pattern 162 being disposed in a second hole HP selected from the plurality of holes HP and disposed adjacent to the first hole HP. For example, the fifth pattern interval dpw5 may be greater than twice the first separation distance da1. In some embodiments, the first dummy pattern 163 may be disposed between the first conductive pattern 162 and the second conductive pattern 162 disposed in different holes HP. The compensation pattern 174 may include a portion placed between the first conductive pattern 162 and the first dummy pattern 163 and a portion placed between the second conductive pattern 162 and the first dummy pattern 163 and may be apart from each of the first dummy pattern 163, the first conductive pattern 162, and the second conductive pattern 162 with the insulating spacer 164 therebetween.

FIG. 8B illustrates planar arrangement relationships between the plurality of conductive patterns 162, the plurality of dummy patterns 163, the insulating spacer 164, and the compensation pattern 174 according to example embodiments, but the example embodiments of the inventive concepts is not limited thereto and the planar arrangement relationships may be modified and changed in various ways by one of ordinary skill in the art within the technical spirit and scope of the inventive concepts.

Hereinafter, a method of manufacturing a semiconductor chip, according to embodiments will be described using specific examples.

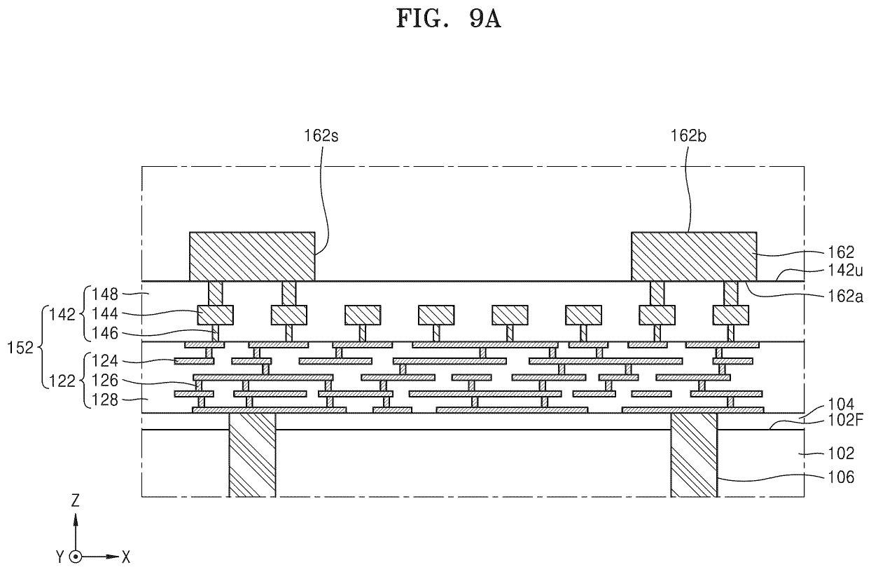

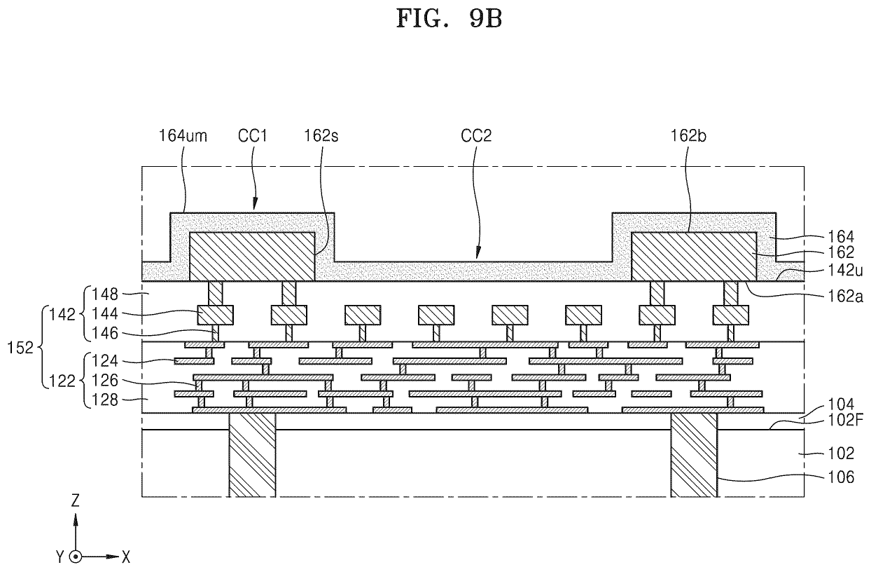

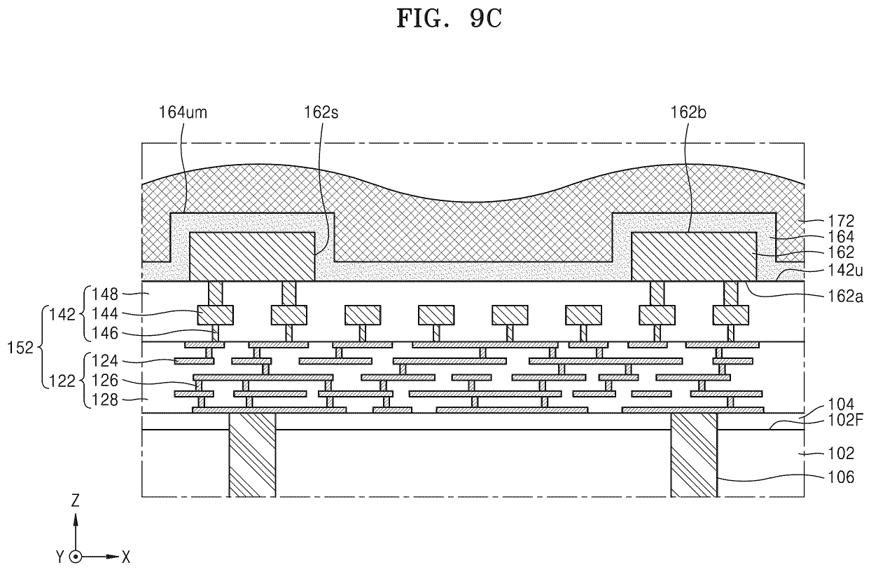

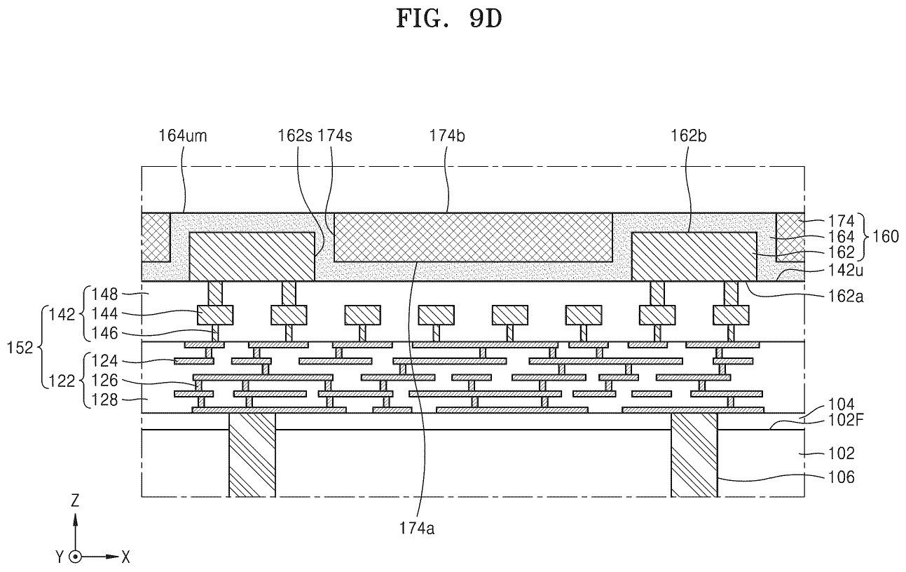

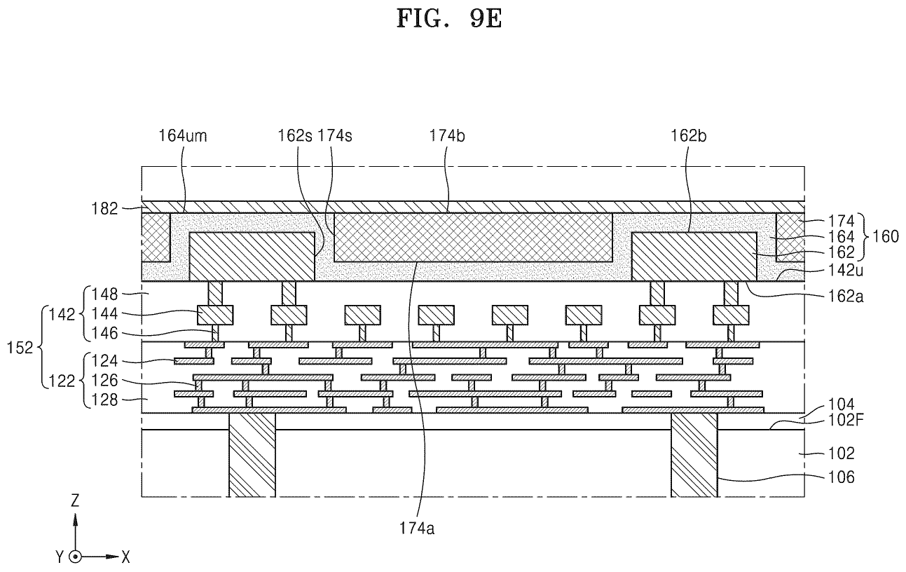

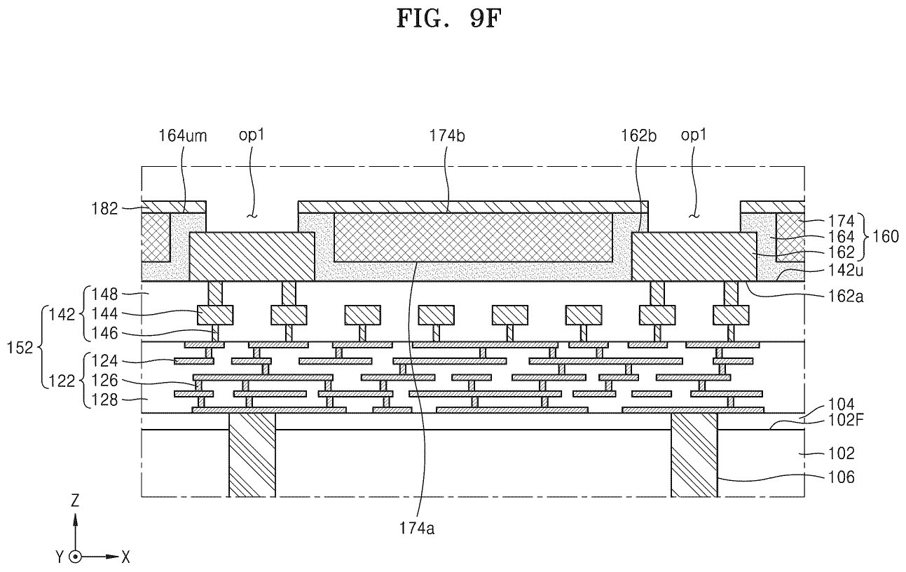

FIGS. 9A to 9F are cross-sectional views shown according to a process sequence to explain a method of manufacturing the semiconductor chip 100 according to some example embodiments. Specifically, FIGS. 9A to 9F are cross-sectional views of a portion corresponding to the area EXA1 in FIG. 1, the cross-sectional views being shown according to a process sequence. Referring to FIGS. 9A to 9F, an example method of manufacturing the semiconductor chip 100 illustrated in FIGS. 1 to 4C will be described. In FIGS. 9A to 9F, the same reference numerals as in FIGS. 1 to 4C indicate the same members, and duplicate descriptions thereof are omitted here.

Referring to FIG. 9A, after a plurality of semiconductor devices are formed on the second surface 102F of the semiconductor substrate 102, an interlayer insulating layer 104 may be formed, and a plurality of through electrodes 106 passing through a portion of the semiconductor substrate 102 and the interlayer insulating layer 104 may be formed. For example, the plurality of through electrodes 106 may pass through the interlayer insulating layer 104, extend into the semiconductor substrate 102, and be partially buried within the semiconductor substrate 102.

Thereafter, an interconnect structure 152 may be formed on the second surface 102F of the semiconductor substrate 102. For example, a first interconnect layer 122 and a second interconnect layer 142 may be sequentially formed on the interlayer insulating layer 104 and the plurality of through electrodes 106.

In some embodiments, the first interconnect layer 122 may be formed by a damascene process using an electroplating method, and the second interconnect layer 142 may be formed by a photo process for depositing a metal material through Physical Vapor Deposition (PVD) and then patterning the deposited material. In some other embodiments, both the first interconnect layer 122 and the second interconnect layer 142 may be formed using a damascene process.

Thereafter, a compensation material layer that covers the upper surface 142u of the second interconnect layer 142 may be formed, and then a pattern mask (not shown) may be formed on the compensation material layer to expose a partial area of the compensation material layer. The plurality of conductive patterns 162 may be formed on the upper surface 142u of the second interconnect layer 142 by removing the partial area of the compensation material layer by using the pattern mask (not shown) as an etch mask. Thereafter, the pattern mask (not shown) may be removed through an ashing process and/or the like. In some embodiments, the plurality of conductive patterns 162 may be in contact with some of the plurality of second interconnect vias 146 exposed through the upper surface 142u of the second interconnect layer 142.

Referring to FIG. 9B, an insulating spacer 164 may be formed to conformally cover the surface of the result of FIG. 9A. In some embodiments, the insulating spacer 164 may conformally cover portions of the second surface 162b of each of the plurality of conductive patterns 162, the sidewall 162s of each of the plurality of conductive patterns 162, and the upper surface 142u of the second interconnect layer 142, the portions not vertically overlapping the plurality of conductive patterns 162. In some embodiments, the thickness of the insulating spacer 164 may be substantially equal to the first separation distance da1 (see FIG. 3).

In some embodiments, the vertical level of a first portion of the insulating spacer 164 that vertically overlaps the plurality of conductive patterns 162 may be higher than the vertical level of a second portion of the insulating spacer 164 in contact with the upper surface 142u of the second interconnect layer 142. For example, the upper surface of the second portion may be disposed to be closer to the second surface 102F of the semiconductor substrate 102 than the upper surface of the first portion, and the plurality of conductive patterns 162 and the insulating spacer 164 may form a concave-convex structure including a plurality of convex portions CC1 and a concave portion CC2.

Referring to FIG. 9C, in the result of FIG. 9B, a compensation material layer 172 covering the upper surface of the concave-convex structure may be formed. In some embodiments, the compensation material layer 172 may be formed to have a sufficient thickness to fill the concave portion CC2 of the concave-convex structure. For example, the upper surface of a portion of the compensation material layer 172 disposed in an area that does not vertically overlap the plurality of conductive patterns 162 may be disposed at a vertical level higher than those of the upper surfaces of the plurality of convex portions CC1 of the concave-convex structure.

In some embodiments, when two adjacent conductive patterns 162 among the plurality of conductive patterns 162 are apart from each other by the second pattern interval dpw2 (see FIG. 4B), the two adjacent conductive patterns 162 may constitute one convex portion CC1. For example, in FIGS. 4A to 4C, the plurality of holes HP may each be an area where one selected from the plurality of convex portions CC1 is formed, and the compensation pattern 174 may be formed from the compensation material layer 172 (see FIG. 9C) that fills the concave portion CC2 defined between the plurality of convex portions CC1, according to a process described below.

Referring to FIG. 9D, in the result of FIG. 9C, the compensation pattern 174 may be formed by planarizing the compensation material layer 172 so that the insulating spacer 164 is exposed. In some embodiments, the planarization process may include a chemical mechanical polishing (CMP) process, an etch-back process, a combination thereof, and/or the like.

In some embodiments, the insulating spacer 164 may function as a stopper in a grinding process for removing and planarizing the compensation material layer 172. The grinding process may be performed so that the uppermost surface um of the insulating spacer 164 is exposed, and the second surface 174b of the compensation pattern 174 and the uppermost surface um of the insulating spacer 164 may be located at the same vertical level. In some embodiments, the plurality of conductive patterns 162 may be surrounded by the insulating spacer 164 and not exposed.

In some embodiments, the compensation pattern 174 may be spaced apart from the plurality of conductive patterns 162 with the insulating spacer 164 therebetween and may fill the concave portion CC2 (FIG. 9B) of the concave-convex structure to reduce pattern density deviation for each area within the frontside interconnect layer 160.

In some other embodiments, in the result of FIG. 9C, the compensation material layer 172 and the insulating spacer 164 may be planarized so that the plurality of conductive patterns 162 are exposed. In this case, a portion of the insulating spacer 164 covering the second surface 162b of each of the plurality of conductive patterns 162 may be removed, and the second surface 162b of each of the plurality of conductive patterns 162 and the second surface 174b of the compensation pattern 174 may be on the same plane. Thereafter, the semiconductor chip 100b described with reference to FIG. 6 may be manufactured by performing the same process as the process described below with reference to FIGS. 9E and 9F.

Referring to FIGS. 9E and 9F together, in the result of FIG. 9D, a frontside dielectric layer 182 covering the frontside interconnect layer 160 may be formed. For example, the frontside dielectric layer 182 may be in contact with the uppermost surface 164 um of the insulating spacer 164 and the second surface 174b of the compensation pattern 174.

Thereafter, a plurality of first openings op1 may be formed to at least partially expose the second surface 162b of each of the plurality of conductive patterns 162. In some embodiments, the plurality of first openings op1 may be formed by forming a pattern mask on the frontside dielectric layer 182 and then removing a portion of the frontside dielectric layer 182 and a portion of the insulating spacer 164 through an etching process.

Referring to FIG. 9F and FIGS. 1 to 4C together, in the result of FIG. 9F, the plurality of frontside bonding pads 184 that individually fill the plurality of first openings op1 may be formed. In some embodiments, a metal seed layer that covers the inner walls and bottom surfaces of the plurality of first openings op1 may be formed, and then a metal core layer may be formed from the metal seed layer through an electroplating process to form the plurality of frontside bonding pads 184.

Thereafter, a portion of the semiconductor substrate 102 may be removed to expose the plurality of through electrodes 106 and form the first surface 102B of the semiconductor substrate 102. In some embodiments, ends of the plurality of through electrodes 106 on the first surface 102B may pass through the semiconductor substrate 102 and protrude from the first surface 102B of the semiconductor substrate 102. Thereafter, a passivation layer 192 may be formed to cover the first surface 102B of the semiconductor substrate 102 and the exposed portions of the plurality of through electrodes 106, and then a polishing process may be performed to form the plurality of through electrodes 106. For example, the lower surfaces of the passivation layer 192 and the plurality of through electrodes 106 may be on the same plane. Thereafter, a backside dielectric layer 194 may be formed to cover the lower surface of the passivation layer 192 and the lower surfaces of the plurality of through electrodes 106, and then a plurality of backside bonding pads 196 respectively connected to the plurality of through electrodes 106 through the backside dielectric layer 194 may be formed.

The method of manufacturing the semiconductor chip 100 according to example embodiments may include forming a concave-convex structure including the plurality of conductive patterns 162 and the insulating spacer 164, and then forming the compensation pattern 174 filling the concave portion CC2 of the concave-convex structure. Because the compensation pattern 174 is apart from the plurality of conductive patterns 162 by the first separation distance da1, which is the thickness of the insulating spacer 164, and is self-aligned, the topology characteristics of the front surface 100F of the semiconductor chip 100 may be improved by separating the plurality of conductive patterns 162 and the compensation pattern 174 with low process difficulty.

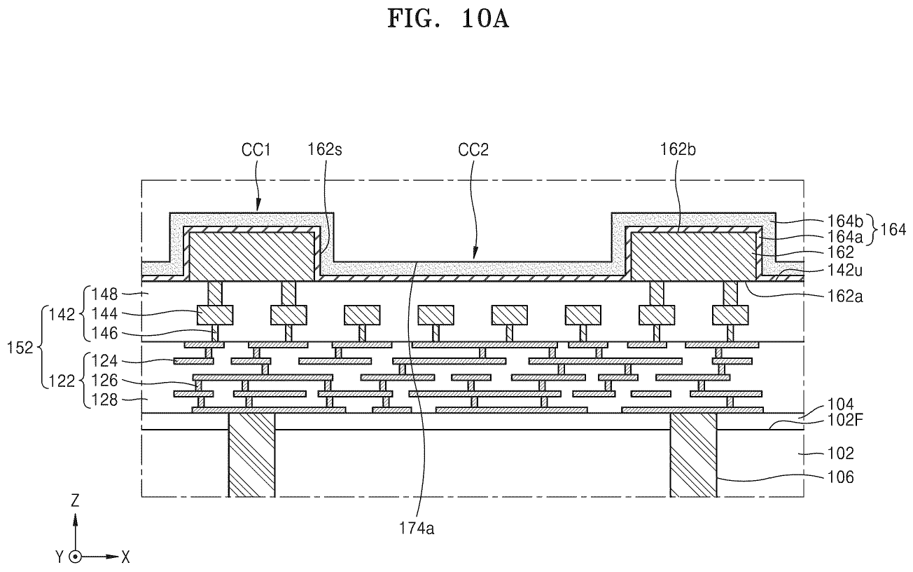

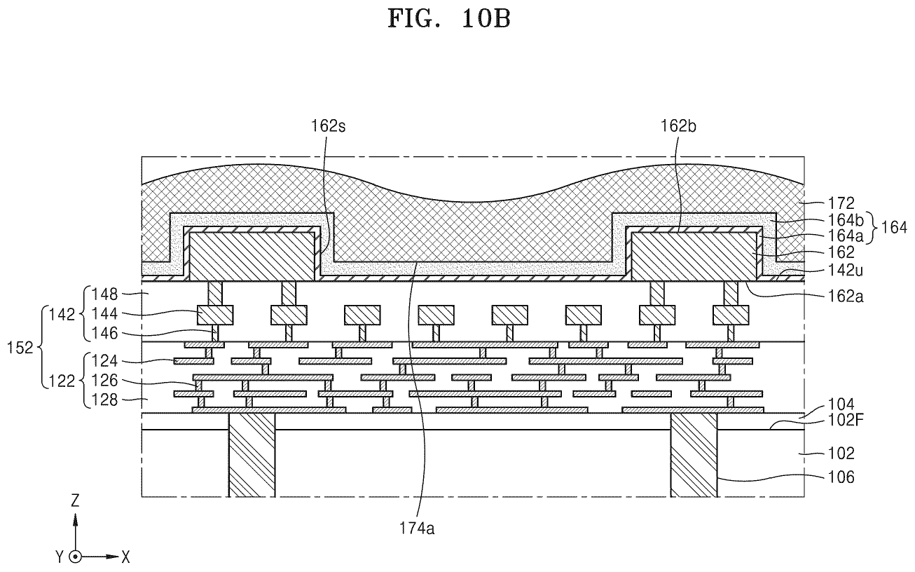

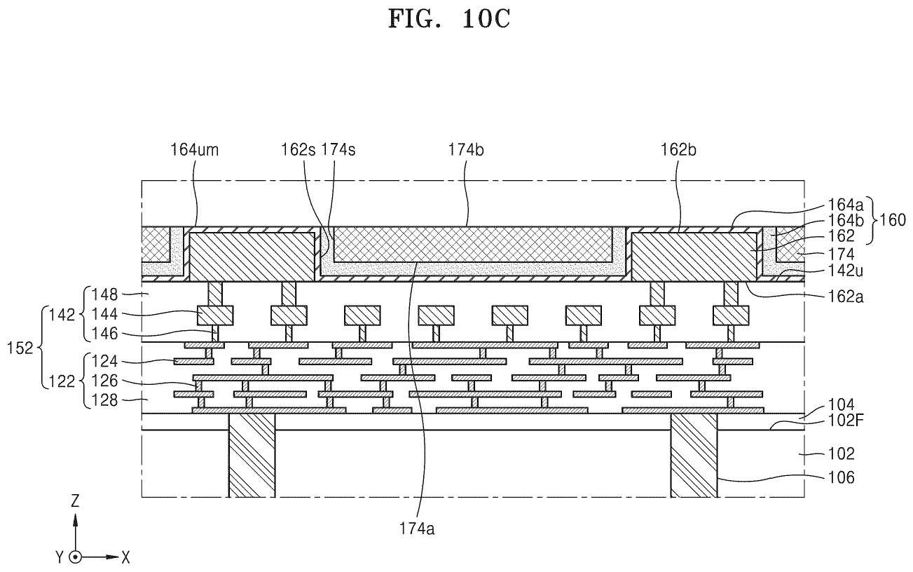

FIGS. 10A to 10C are cross-sectional views illustrating a method of manufacturing the semiconductor chip 100a according to some other embodiments. Specifically, FIGS. 10A to 10C are cross-sectional views of a portion corresponding to FIG. 5A, the cross-sectional views being shown according to a process sequence. Referring to FIGS. 10A to 10C, an example method of manufacturing the semiconductor chip 100a illustrated in FIGS. 5A and 5B will be described. In FIGS. 10A to 10C, the same reference numerals as in FIGS. 1 to 9F indicate the same members, and redundant descriptions thereof are omitted here.

An interconnect structure 152 including a first interconnect layer 122 and a second interconnect layer 142 may be formed on the second surface 102F of the semiconductor substrate 102 in the same manner as described with reference to FIG. 9A, and a process of forming the plurality of conductive patterns 162 on the upper surface 142u of the second interconnect layer 142 may be performed.

Referring to FIG. 10A, an insulating spacer 164 may be formed by sequentially forming the first spacer layer 164a and the second spacer layer 164b that conformally cover the result of FIG. 9A. For example, the first spacer layer 164a may conformally cover portions of the second surface 162b of each of the plurality of conductive patterns 162, the sidewall 162s of each of the plurality of conductive patterns 162, and the upper surface 142u of the second interconnect layer 142, the portions not vertically overlapping the plurality of conductive patterns 162. The second spacer layer 164b may be disposed on the first spacer layer 164a, and the first spacer layer 164a may be covered by the second spacer layer 164b. The second spacer layer 164b may be apart from the plurality of conductive patterns 162 and the interconnect structure 152 with the first spacer layer 164a therebetween. In some embodiments, the plurality of conductive patterns 162, the first spacer layer 164a, and the second spacer layer 164b may form a concave-convex structure including a convex portion CC1 and a concave portion CC2.

Referring to FIG. 10B, in the result of FIG. 10A, a compensation material layer 172 covering the upper surface of the concave-convex structure may be formed. The compensation material layer 172 may fill the concave portion CC2 of the concave-convex structure and may be apart from the plurality of conductive patterns 162 and the interconnect structure 152 with the first spacer layer 164a and the second spacer layer 164b therebetween.

Referring to FIG. 10C, a compensation pattern 174 may be formed by planarizing the result of FIG. 10B so that the first spacer layer 164a is exposed. In the planarization process, a portion of the compensation material layer 172 and a portion of the second spacer layer 164b may be removed. For example, the first spacer layer 164a may function as a stop layer in the planarization process. In FIG. 10B, the second spacer layer 164b that vertically overlaps the plurality of conductive patterns 162 may be removed, and the second surface 162b of each of the plurality of conductive patterns 162 may be covered by the first spacer layer 164a. In some embodiments, the planarization process may include a chemical mechanical polishing (CMP) process, an etch-back process, a combination thereof, and/or the like.

In some embodiments, the first spacer layer 164a may thereby be spaced apart from the compensation pattern 174 with the second spacer layer 164b therebetween. The uppermost surface 164 um of the insulating spacer 164 may be composed of the uppermost surface of the first spacer layer 164a and the uppermost surface of the second spacer layer 164b.

Thereafter, in the result of FIG. 10C, as described with reference to FIGS. 9E and 9F, a frontside dielectric layer 182, which covers the upper surface of each of the first spacer layer 164a, a second spacer layer 164b, and a compensation pattern 174, may be formed, and then a plurality of first openings op1 may be formed. Thereafter, the semiconductor chip 100a described with reference to FIGS. 5A and 5B may be formed by forming a plurality of frontside bonding pads 184 that fill the plurality of first openings op1.

FIG. 11 is a cross-sectional view illustrating a method of manufacturing the semiconductor chip 100c according to some other embodiments. Specifically, FIG. 11 is a cross-sectional view of a portion corresponding to FIG. 6. Referring to FIG. 11, an example method of manufacturing the semiconductor chip 100c illustrated in FIG. 6 will be described. In FIG. 11, the same reference numerals as in FIGS. 1 to 10C indicate the same members, and duplicated descriptions thereof are omitted here.

An interconnect structure 152 may be formed on the second surface 102F of the semiconductor substrate 102 by using the method described with reference to FIGS. 9A to 9E, a frontside interconnect layer 160 including the plurality of conductive patterns 162, a compensation pattern 174, and an insulating spacer 164 may be formed on the interconnect structure 152, and then a frontside dielectric layer 182 may be formed on the frontside interconnect layer 160.

Referring to FIG. 11, in the result of FIG. 9E, a plurality of first openings op1 exposing at least a portion of the second surface 162b of each of the plurality of conductive patterns 162 and a plurality of second openings op2 exposing at least a portion of the second surface 174b of the compensation pattern 174 may be formed. For example, the plurality of first openings op1 and the plurality of second openings op2 may be formed together in the same process.

Thereafter, a plurality of frontside bonding pads 184 filling the plurality of first openings op1 and a plurality of first frontside dummy pads 186 filling the plurality of second openings op2 may be formed, and thus, the semiconductor chip 100c described with reference to FIG. 7 may be formed. In some embodiments, the plurality of frontside bonding pads 184 and the plurality of first frontside dummy pads 186 may be formed together in the same process. For example, after a metal seed layer covering the inner wall and bottom surface of each of the plurality of first and second openings op1 and op2 and the upper surface of the frontside dielectric layer 182 is formed, a metal core layer may be formed from the metal seed layer through electroplating. Thereafter, a polishing process may be performed so that the frontside dielectric layer 182 is exposed to form the plurality of frontside bonding pads 184 and the plurality of first frontside dummy pads 186.

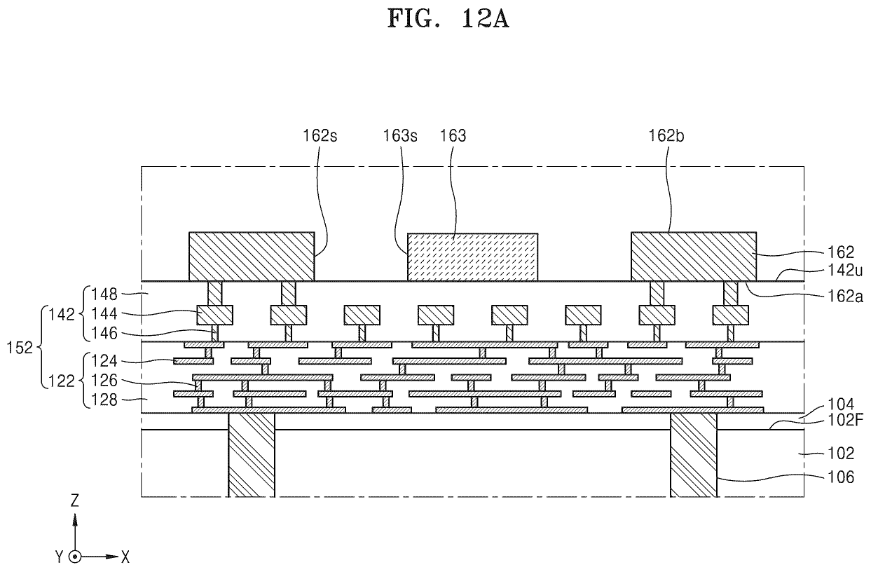

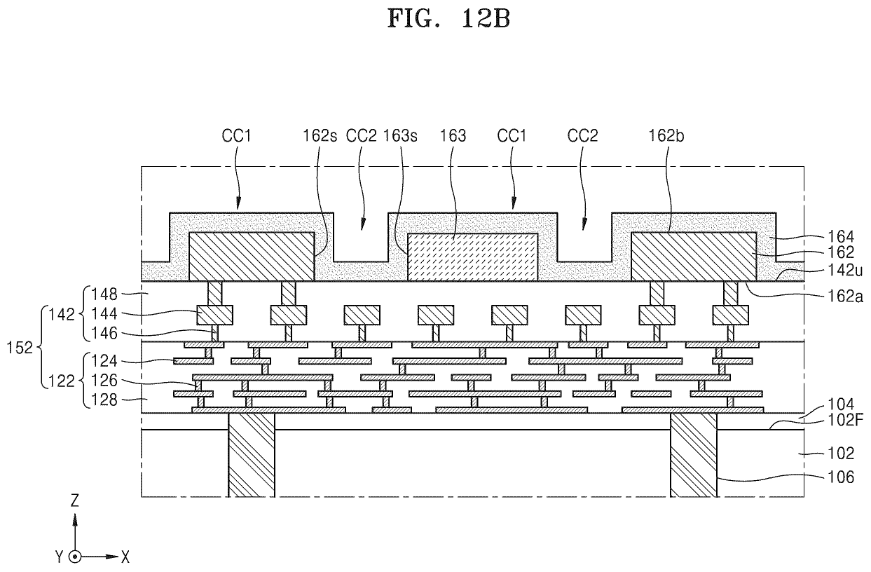

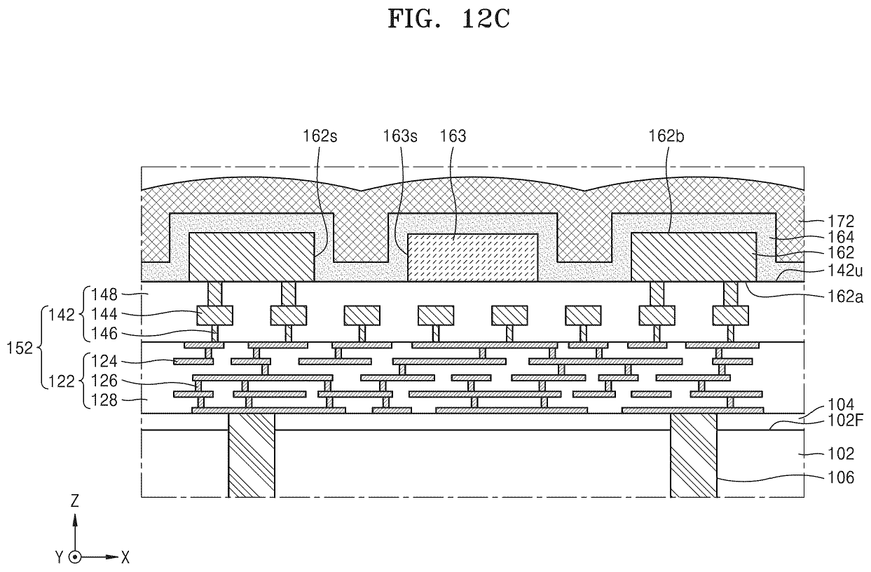

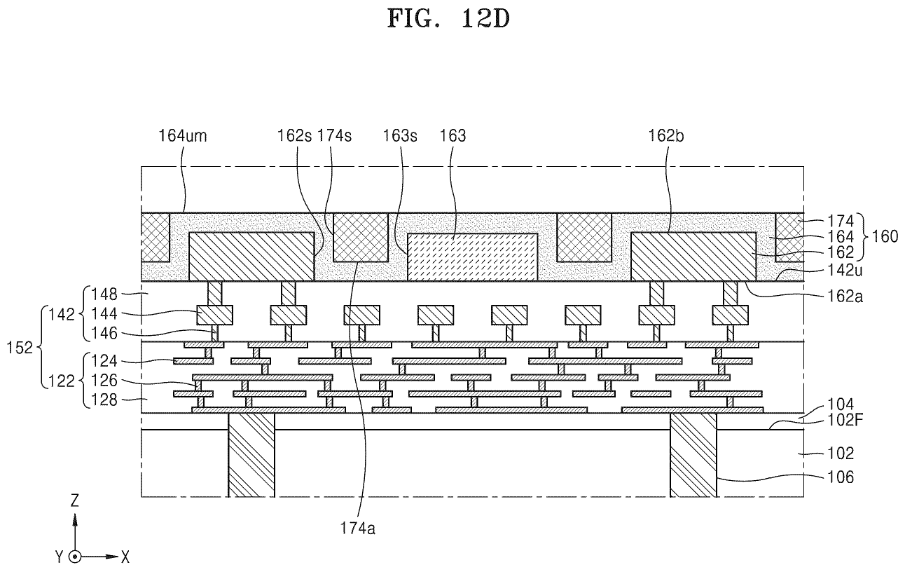

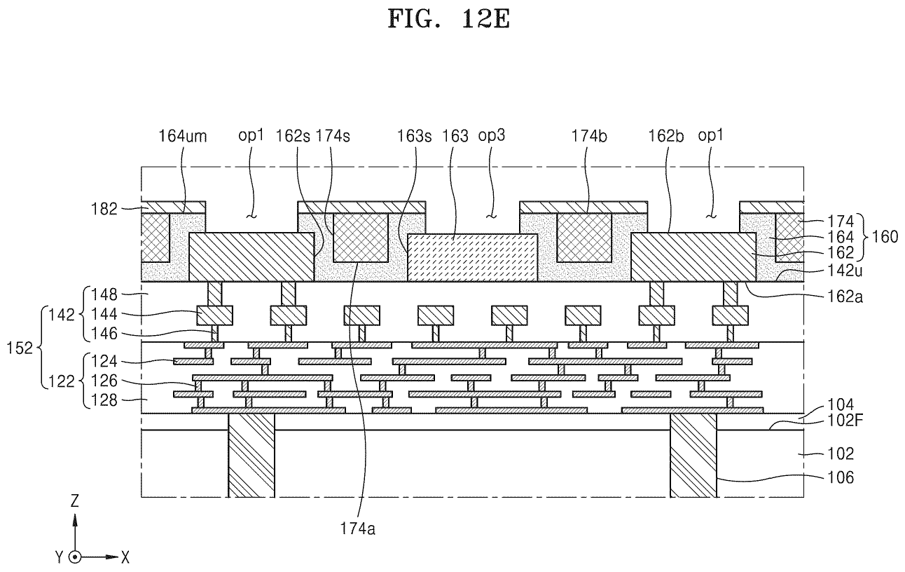

FIGS. 12A to 12E are cross-sectional views shown according to a process sequent to explain a method of manufacturing the semiconductor chip 100d according to some other embodiments. Specifically, FIGS. 12A to 12E are cross-sectional views of a portion corresponding to FIG. 8A, the cross-sectional views being shown according to a process sequence. Referring to FIGS. 12A to 12E, an example method of manufacturing the semiconductor chip 100d illustrated in FIGS. 8A and 8B will be described. In FIGS. 12A to 12E, the same reference numerals as in FIGS. 1 to 11 indicate the same members, and duplicate descriptions thereof are omitted here.

Referring to FIG. 12A, an interconnect structure 152 including a first interconnect layer 122 and a second interconnect layer 142 may be formed on the second surface 102F of the semiconductor substrate 102 in the same manner as described with reference to FIG. 9A, and then a plurality of conductive patterns 162 and a plurality of dummy patterns 163 may be formed on the interconnect structure 152.

In some embodiments, the plurality of conductive patterns 162 may be formed to contact the plurality of second interconnect vias 146 and be connected to the second interconnect line 144, but may be formed not to contact the plurality of second interconnect vias 146. For example, the plurality of dummy patterns 163 may be in contact with the second interconnect insulating layer 148 and not be connected to the second interconnect line 144.

In some embodiments, the plurality of dummy patterns 163 may be formed in the same process as the plurality of conductive patterns 162, and the plurality of conductive patterns 162 and the plurality of dummy patterns 163 may include the same material. In some embodiments, the upper surface of each of the plurality of dummy patterns 163 may be at the same vertical level as the second surface 162b of each of the plurality of conductive patterns 162.

Referring to FIG. 12B, in the result of FIG. 12A, a plurality of conductive patterns 162, a plurality of dummy patterns 163, and an insulating spacer 164 covering a portion of the upper surface 142u of the second interconnect layer 142, the portion not vertically overlapping the plurality of conductive patterns 162 and the plurality of dummy patterns 163, may be formed. For example, the insulating spacer 164 may cover the upper surface and sidewall of each of the plurality of dummy patterns 163.

In some embodiments, a portion of the insulating spacer 164 that covers the plurality of conductive patterns 162 and the plurality of dummy patterns 163 may be placed at a higher vertical level than a portion of the insulating spacer 164 that does not cover the plurality of conductive patterns 162 and the plurality of dummy patterns 163. The plurality of conductive patterns 162, the plurality of dummy patterns 163, and the insulating spacer 164 may form a concave-convex structure including a convex portion CC1 and a concave portion CC2.

Referring to FIGS. 12C and 12D together, in the result of FIG. 12B, a compensation material layer 172 covering the concavo-convex structure may be formed. For example, the compensation material layer 172 may fill the concave portion CC2 of the concave-convex structure. Thereafter, the compensation material layer 172 may be planarized so that the insulating spacer 164 is exposed to form the compensation pattern 174. The second surface 174b of the compensation pattern 174 and the uppermost surface 164um of the insulating spacer 164 may be on the same plane. In some embodiments, the planarization process may include a chemical mechanical polishing (CMP) process, an etch-back process, a combination thereof, and/or the like.

Referring to FIG. 12E, in the result of FIG. 12D, after a frontside dielectric layer 182 covering the exposed second surface 174b of the compensation pattern 174 and the uppermost surface 164um of the insulating spacer 164 is formed, a portion of the frontside dielectric layer 182 and a portion of the insulating spacer 164 may be removed to form a plurality of first openings op1 that respectively expose the plurality of conductive patterns 162 and a plurality of third openings op3 that respectively expose the plurality of dummy patterns 163. In some embodiments, the plurality of first openings op1 and the plurality of third openings op3 may be formed together in the same process. Thereafter, a plurality of frontside bonding pads 184 that fill the first openings op1 and a plurality of second frontside dummy pads 187 that fill the third openings op3 may be formed.

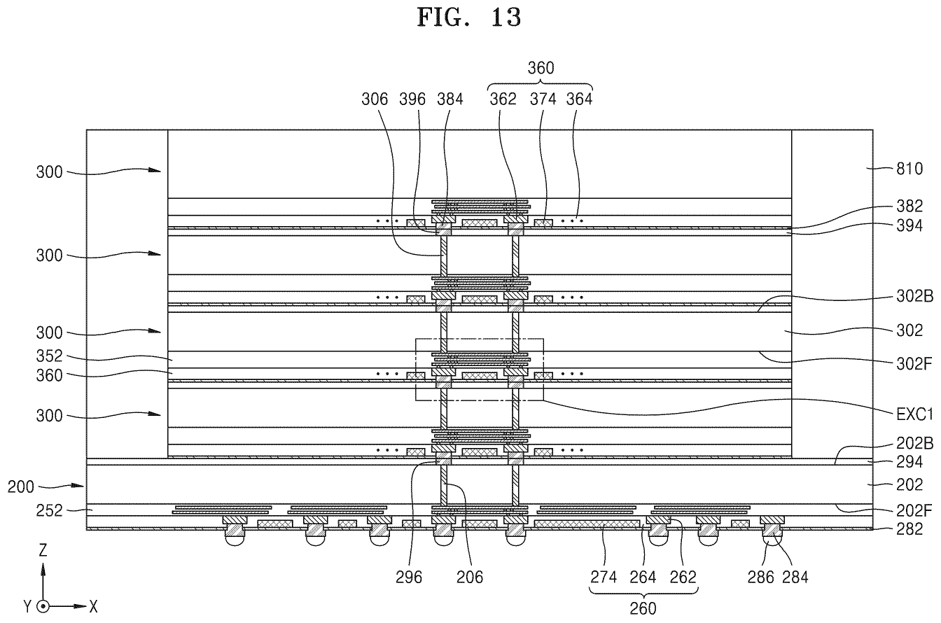

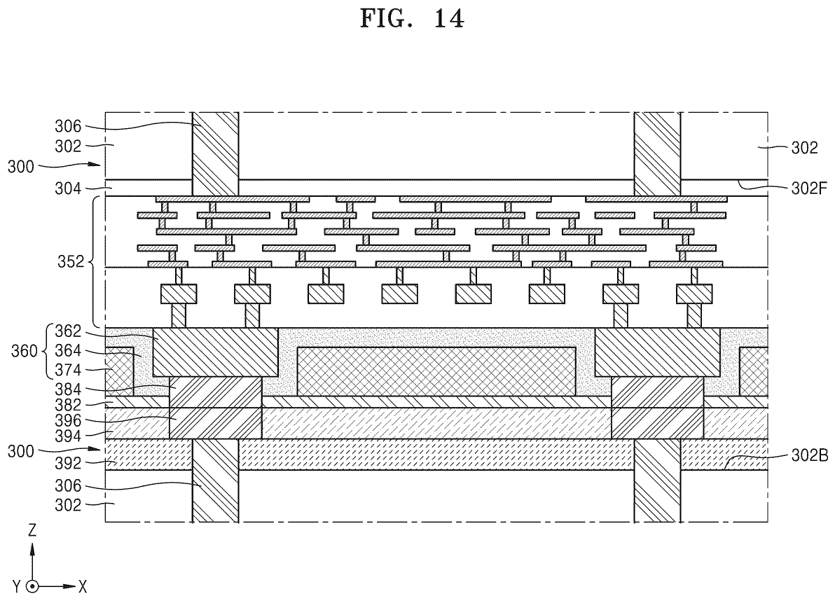

FIG. 13 is a cross-sectional view showing a semiconductor package 1000 according to example embodiments. FIG. 14 is an enlarged view of the area marked “EXC1” in FIG. 11.

Referring to FIGS. 13 and 14, the semiconductor package 1000 may include a first semiconductor chip 200 and a plurality of second semiconductor chips 300. The plurality of second semiconductor chips 300 may be stacked on the first semiconductor chip 200 in the vertical direction (the Z direction). In FIG. 5, the semiconductor package 1000 is shown as including four second semiconductor chips 300, but the number of second semiconductor chips 300 is not limited thereto. For example, the semiconductor package 1000 may include two or more second semiconductor chips 300. In example embodiments, the semiconductor package 1000 may include a multiple of 4 second semiconductor chips 300. In the present specification, the semiconductor package 1000 may be referred to as a sub-semiconductor package.

According to example embodiments, the first semiconductor chip 200 may be electrically connected to the lowermost second semiconductor chip 300 among the plurality of second semiconductor chips 300, exchange signals, and provide power and ground. Among the plurality of second semiconductor chips 300, two adjacent second semiconductor chips 300 may be electrically connected to each other, exchange signals, and provide or receive power and ground.

According to example embodiments, the first semiconductor chip 200 may include a first semiconductor substrate 202 having an active surface 202F and an inactive surface 202B opposite to each other, a first interconnect structure 252 formed on the active surface 202F of the first semiconductor substrate 202 and including a plurality of interconnect lines and a plurality of interconnect vias, a plurality of first through electrodes 206 connected to some of the plurality of interconnect lines of the first interconnect structure 252 and passing through the first semiconductor substrate 202, a plurality of first backside bonding pads 296 connected to the plurality of first through electrodes 206 on the inactive surface 202B of the first semiconductor substrate 202, and a first backside dielectric layer 294 surrounding the sidewall of each of the plurality of first backside bonding pads 296. Although not shown in FIG. 13, the first semiconductor chip 200 may include a first passivation layer (not shown) surrounding the upper sidewalls of the plurality of through electrodes 106 on the inactive surface 202B of the first semiconductor substrate 202, and a first interlayer insulating layer (not shown) for protecting a plurality of semiconductor devices between the active surface 202F of the first semiconductor substrate 202 and the first interconnect structure 252.

The active surface 202F of the first semiconductor substrate 202 may be the frontside surface of the first semiconductor substrate 202, and the inactive surface 202B of the first semiconductor substrate 202 may be the backside surface of the first semiconductor substrate 202. In FIG. 13, the active surface 202F of the first semiconductor substrate 202 may have a face-down arrangement to face downward, and the active surface 202F of the first semiconductor substrate 202 may be referred to as the lower surface of the first semiconductor substrate 202.

According to some example embodiments, the first semiconductor chip 200 may include a first frontside interconnect layer 260 and a first frontside dielectric layer 282 sequentially stacked on the lower surface of the first interconnect structure 252. The first frontside interconnect layer 260 may be apart from the first semiconductor substrate 202 with the first interconnect structure 252 therebetween. According to example embodiments, the first frontside interconnect layer 260 may include a plurality of first conductive patterns 262, a first compensation pattern 274, and a first insulating spacer 264 placed between the plurality of first conductive patterns 262 and the first compensation pattern 274. The plurality of first conductive patterns 262 may be disposed closer to the active surface 202F of the first semiconductor substrate 202 than the first compensation pattern 274. The first insulating spacer 264 may include a portion placed between the first compensation pattern 274 and the first interconnect structure 252, a portion placed between the plurality of first conductive patterns 262 and the first frontside dielectric layer 282, and a portion placed between the plurality of first conductive patterns 262 and the first compensation pattern 274. The first frontside dielectric layer 282 may be in contact with the lower surface of the first compensation pattern 274 and may be apart from the plurality of first conductive patterns 262 with the first insulating spacer 264 therebetween. According to example embodiments, the first semiconductor chip 200 may include a plurality of first frontside bonding pads 284 that pass through the first frontside dielectric layer 282 and the first insulating spacer 264 and respectively contact the plurality of first conductive patterns 262. In some embodiments, each of the first frontside bonding pads 284 may include a first portion surrounded by the first frontside dielectric layer 282 and the first insulating spacer 264, and a second portion disposed on the lower surface of the first frontside dielectric layer 282. The sidewall of the first portion may face the first compensation pattern 274 with the first insulating spacer 264 therebetween. According to example embodiments, the semiconductor package 1000 may include a plurality of connection bumps 286 respectively attached to the plurality of first frontside bonding pads 284 of the first semiconductor chip 200.

The first semiconductor substrate 202 is substantially the same as or similar to the semiconductor substrate 102 shown in FIGS. 1 and 2, the plurality of first through electrodes 206 are substantially the same as or similar to the plurality of through electrodes 106 shown in FIGS. 1 and 2, the first interconnect structure 252 is substantially the same as or similar to the interconnect structure 152 shown in FIGS. 1 to 3, the plurality of first backside bonding pads 296 are substantially the same as or similar to the plurality of backside bonding pads 196 shown in FIG. 1, the first backside dielectric layer 294 is substantially the same as or similar to the backside dielectric layer 194 shown in FIG. 1, and the first passivation layer (not shown) is substantially the same as or similar to the passivation layer 192 shown in FIG. 1, and thus, detailed descriptions thereof are omitted. The plurality of first conductive patterns 262, the first insulating spacer 264, and the first compensation pattern 274 are substantially the same as or similar to the plurality of conductive patterns 162, the insulating spacer 164, and the compensation pattern 174 shown in FIGS. 1 to 4C, respectively, the first frontside dielectric layer 282 is substantially the same as or similar to the frontside dielectric layer 182 shown in FIGS. 1 to 3, and the plurality of first frontside bonding pads 284 are substantially the same as or similar to the plurality of frontside bonding pads 184 shown in FIGS. 1 to 3, and thus, detailed descriptions thereof are omitted. However, the example embodiments are not limited thereto. For example, the first frontside interconnect layer 260 may be otherwise substantially the same as or similar to the frontside interconnect layer 160 of FIGS. 1 to 8B.

According to example embodiments, the second semiconductor chip 300 may include a second semiconductor substrate 302 having an active surface 302F and an inactive surface 302B opposite to each other, a second interconnect structure 352 formed on the active surface 302F of the second semiconductor substrate 302 and including a plurality of interconnect lines and a plurality of interconnect vias, a plurality of second through electrodes 306 connected to some of the plurality of interconnect lines of the second interconnect structure 352 and passing through the second semiconductor substrate 302, a second passivation layer 392 formed on the inactive surface 302B of the second semiconductor substrate 302, a plurality of second backside bonding pads 396 connected to the plurality of second through electrodes 306 on the second passivation layer 392, and a second backside dielectric layer 394 surrounding the sidewall of each of the plurality of second backside bonding pads 396. According to example embodiments, the second semiconductor chip 300 may include a second interlayer insulating layer 304 placed between the second semiconductor substrate 302 and the second interconnect structure 352 to protect semiconductor devices formed on the active surface 302F of the second semiconductor substrate 302.

The active surface 302F of the second semiconductor substrate 302 may be the frontside surface of the second semiconductor substrate 302, and the inactive surface 302B of the second semiconductor substrate 302 may be the backside surface of the second semiconductor substrate 302. In FIGS. 13 and 14, the active surface 302F of the second semiconductor substrate 302 may have a face-down arrangement to face downward, and the active surface 302F of the second semiconductor substrate 302 may be referred to as the lower surface of the second semiconductor substrate 302.

According to example embodiments, the second semiconductor chip 300 may include a second frontside interconnect layer 360 and a second frontside dielectric layer 382 sequentially stacked on the lower surface of the second interconnect structure 352. The second frontside interconnect layer 360 may be apart from the second semiconductor substrate 302 with the second interconnect structure 352 therebetween. According to example embodiments, the second frontside interconnect layer 360 may include a plurality of second conductive patterns 362, a second compensation pattern 374, and a second insulating spacer 364 placed between the plurality of second conductive patterns 362 and the second compensation pattern 374. The plurality of second conductive patterns 362 may be disposed closer to the active surface 302F of the second semiconductor substrate 302 than the second compensation pattern 374. The second insulating spacer 364 may include a portion placed between the second compensation pattern 374 and the second interconnect structure 352, a portion placed between the plurality of second conductive patterns 362 and the second frontside dielectric layer 382, and a portion placed between the plurality of second conductive patterns 362 and the second compensation pattern 374. The second frontside dielectric layer 382 may be in contact with the lower surface of the second compensation pattern 374 and may be apart from the plurality of second conductive patterns 362 with the second insulating spacer 364 therebetween. According to example embodiments, the second semiconductor chip 300 may include a plurality of second frontside bonding pads 384 that pass through the second frontside dielectric layer 382 and the second insulating spacer 364 and respectively contact the plurality of second conductive patterns 362. In some embodiments, each of the second frontside bonding pads 384 may be surrounded by the second frontside dielectric layer 382 and the second insulating spacer 364. The sidewall of each of the plurality of second frontside bonding pads 384 may include a portion that faces the second compensation pattern 374 with the second insulating spacer 364 therebetween.

The second semiconductor substrate 302 is substantially the same as or similar to the semiconductor substrate 102 shown in FIGS. 1 and 2, the plurality of second through electrodes 306 are substantially the same as or similar to the plurality of through electrodes 106 shown in FIGS. 1 and 2, the second interconnect structure 352 is substantially the same as or similar to the interconnect structure 152 shown in FIGS. 1 to 3, the plurality of second backside bonding pads 396 are substantially the same as or similar to the plurality of backside bonding pads 196 shown in FIG. 1, the second backside dielectric layer 394 is substantially the same as or similar to the backside dielectric layer 194 shown in FIG. 1, and the second passivation layer 392 is substantially the same as or similar to the passivation layer 192 shown in FIG. 1, and thus, detailed descriptions thereof are omitted. The plurality of second conductive patterns 362, the second insulating spacer 364, and the second compensation pattern 374 are substantially the same as or similar to the plurality of conductive patterns 162, the insulating spacer 164, and the compensation pattern 174 shown in FIGS. 1 to 4C, respectively, the second frontside dielectric layer 382 is substantially the same as or similar to the frontside dielectric layer 182 shown in FIGS. 1 to 3, and the plurality of second frontside bonding pads 384 are substantially the same as or similar to the plurality of frontside bonding pads 184 shown in FIGS. 1 to 3, and thus, detailed descriptions thereof are omitted. However, the example embodiments are not limited thereto. For example, the second frontside interconnect layer 360 may be otherwise substantially the same as or similar to the frontside interconnect layer 160 of FIGS. 1 to 8B.

In some embodiments, the uppermost second semiconductor chip 300 among the plurality of second semiconductor chips 300 may not include the plurality of second through electrodes 306, the second passivation layer 392, the second backside dielectric layer 394, and the plurality of second backside bonding pads 396. In some embodiments, the vertical height of the uppermost second semiconductor chip 300 among the plurality of second semiconductor chips 300 may be greater than the vertical height of each of the remaining second semiconductor chips 300. The vertical heights of the remaining second semiconductor chips 300 may be substantially the same.

In some embodiments, the semiconductor package 1000 including the first semiconductor chip 200 and the plurality of second semiconductor chips 300 may be referred to as a high bandwidth memory (HBM) DRAM semiconductor chip. For example, the first semiconductor chip 200 may be a buffer chip including a serial-parallel conversion circuit and controlling the plurality of second semiconductor chips 300, and the plurality of second semiconductor chips 300 may be core chips including DRAM memory cells. In example embodiments, the first semiconductor chip 200 may be referred to as a master chip, and each of the plurality of second semiconductor chips 300 may be referred to as a slave chip.

In some other embodiments, at least one of the first semiconductor chip 200 and the plurality of second semiconductor chips 300 may be a memory semiconductor chip. At least one of the first semiconductor chip 200 and the plurality of second semiconductor chips 300 may be a logic chip. Examples of the logic chip may include a CPU chip, a GPU chip, and/or an AP chip.

As shown in FIG. 14, two second semiconductor chips 300 adjacent to each other in the vertical direction (the Z direction) may be bonded using a direct bonding method, for example, a hybrid direct bonding method. The plurality of second backside bonding pads 396 of the lower second semiconductor chip 300 of the two adjacent second semiconductor chips 300 may be aligned and bonded to the plurality of second frontside bonding pads 384 of the upper second semiconductor chip 300 of the two adjacent second semiconductor chips 300 in the vertical direction (e.g., the Z direction). In addition, the second backside dielectric layer 394 of the lower second semiconductor chip 300 may be bonded to the second frontside dielectric layer 382 of the upper second semiconductor chip 300. The surface of the second backside dielectric layer 394 of the lower second semiconductor chip 300 and the surface of the second frontside dielectric layer 382 of the upper second semiconductor chip 300 may each have a bonding force suitable for bonding through plasma treatment and/or wet treatment. For example, bonding between two adjacent second semiconductor chips 300 may be achieved by contacting the bonding surface of the lower second semiconductor chip 300 with the bonding surface of the upper second semiconductor chip 300 and then applying heat to connect the plurality of second backside bonding pads 396 and the second backside dielectric layer 394 of the lower second semiconductor chip 300 to the plurality of second frontside bonding pads 384 and the second frontside dielectric layer 382 of the upper second semiconductor chip 300, respectively.

In some embodiments, the first semiconductor chip 200 and the lowermost of the second semiconductor chips 300 may be bonded using a direct bonding method that is substantially the same as or similar to the bonding method between the two second semiconductor chips 300 adjacent to each other in the vertical direction (the Z direction). For example, the plurality of first backside bonding pads 296 of the first semiconductor chip 200 and the plurality of second frontside bonding pads 384 of the lowermost second semiconductor chip 300 may be aligned and bonded to each other in the vertical direction (e.g., the Z direction). For example, the upper surface of the first backside dielectric layer 294 of the first semiconductor chip 200 may be in contact with the lower surface of the second frontside dielectric layer 382 of the second semiconductor chip 300.

According to some example embodiments, the semiconductor package 1000 may further include a molding layer 810 disposed on the first semiconductor chip 200 and covering the side surfaces of the plurality of second semiconductor chips 300. The molding layer 810 may cover a portion of the upper surface of the first semiconductor chip 200, the portion being not covered by the plurality of second semiconductor chips 300. In example embodiments, the molding layer 810 may not cover the upper surface of the uppermost second semiconductor chip 300. In other example embodiments, the molding layer 810 may be formed to further cover the upper surface of the uppermost second semiconductor chip 300. The molding layer 810 may include, for example, epoxy mold compound (EMC).

In a semiconductor package according to a comparative example, when two semiconductor chips not including compensation patterns according to example embodiments are bonded by a direct bonding method, the topology of the bonding interface between the two semiconductor chips is degraded due to residual stress of a plurality of conductive patterns of a frontside interconnect layer, thereby reducing bonding reliability between the two semiconductor chips.

According to some example embodiments, the compensation pattern 374 may fill empty areas between the plurality of conductive patterns 362 within the frontside interconnect layer 360 to equalize the pattern density of the frontside interconnect layer 360. Accordingly, when two or more semiconductor chips are bonded by direct bonding, the surface distortion of the bonding interface may be reduced, voids or the peeling of insulating layers occurring at a bonding surface may be suppressed, and bonding reliability between the two semiconductor chips being bonded may be improved.

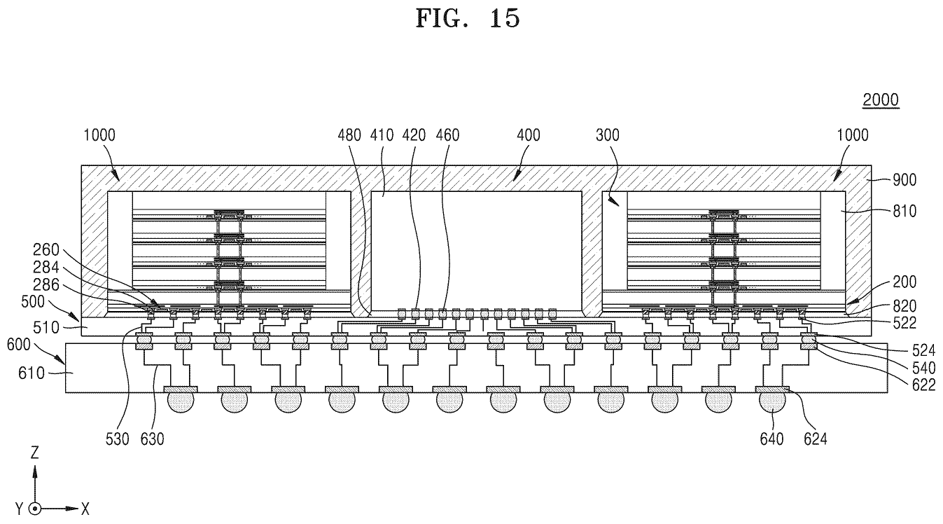

FIG. 15 is a cross-sectional view showing a semiconductor package 2000 according to example embodiments.

Referring to FIG. 15, the semiconductor package 2000 may include an interposer 500, a main board 600 on which the interposer 500 is mounted, at least one sub-semiconductor package 1000 attached to the interposer 500 and including a first semiconductor chip 200 and a plurality of second semiconductor chips 300, and a third semiconductor chip 400. In FIG. 14, the at least one sub-semiconductor package 1000 may correspond to the semiconductor package 1000 described with reference to FIGS. 13 and 14. In the present specification, the semiconductor package 2000 may also be referred to as a system.

According to some example embodiments, the at least one sub-semiconductor package 1000 may be attached to the interposer 500 through a plurality of first connection bumps 286. The plurality of first connection bumps 286 may be attached to a plurality of first frontside bonding pads 284 and electrically connected to the plurality of first conductive patterns 262 of the first semiconductor chip 200 described with reference to FIG. 13 and a plurality of interconnect lines and a plurality of interconnect vias of the first interconnect structure 252 of the first semiconductor chip 200. The plurality of first connection bumps 286 may provide at least one of a signal, power, or ground for the sub-semiconductor package 1000.

In FIG. 15, the semiconductor package 2000 is shown as including two sub-semiconductor packages 1000, but the inventive concepts are not limited thereto. For example, the semiconductor package 2000 may include one sub-semiconductor package 1000 or may include three or more sub-semiconductor packages 1000.

The third semiconductor chip 400 may include a third semiconductor substrate 410 having an active surface on which a semiconductor device is formed, and a plurality of connection pads 420. In example embodiments, each of the plurality of connection pads 420 may include at least one of aluminum, copper, and nickel. The third semiconductor chip 400 may be attached to the interposer 500 through a plurality of second connection bumps 460. The plurality of second connection bumps 460 may be attached to the plurality of connection pads 420. The third semiconductor chip 400 may be a logic chip. For example, the third semiconductor chip 400 may be a CPU chip, a GPU chip, and/or an AP chip.

The third semiconductor substrate 410 may be substantially similar to the first semiconductor substrate 202 and/or the second semiconductor substrate 302 shown in FIG. 13, the second connection bump 460 is substantially similar to the first connection bump 286, and thus, detailed descriptions are omitted.

According to some example embodiments, the interposer 500 may include a base layer 510, a plurality of first upper pads 522 and a plurality of first lower pads 524 respectively disposed on the upper surface and lower surface of the base layer 510, and a plurality of first interconnect paths 530 that electrically connect the first upper pads 522 to the first lower pads 524 through the base layer 510. The base layer 510 may include, e.g., semiconductor, glass, ceramic, or plastic. For example, the base layer 510 may include silicon. The plurality of first interconnect paths 530 may include an interconnect layer connected to the plurality of first upper pads 522 and/or the plurality of first lower pads 524 on the upper surface and/or the lower surface of the base layer 510, and/or an internal through electrode provided inside the base layer 510 to electrically connect the plurality of first upper pads 522 to the plurality of first lower pads 524. A plurality of first connection bumps 286, which electrically connect the sub-semiconductor package 1000 to the interposer 500, or a plurality of second connection bumps 460, which electrically connect the third semiconductor chip 400 to the interposer 500, may be electrically connected to the plurality of first upper pads 522.

A first underfill layer 820 may be placed between the sub-semiconductor package 1000 and the interposer 500, and a second underfill layer 480 may be placed between the third semiconductor chip 400 and the interposer 500. The first underfill layer 820 may surround the first connection bumps 265, and the second underfill layer 480 may surround the second connection bumps 460.

The semiconductor package 2000 may further include a package molding layer 900 surrounding the side surfaces of the sub-semiconductor package 1000 and the third semiconductor chip 400 on the interposer 500. The package molding layer 900 may include, for example, EMC. In example embodiments, the package molding layer 900 may cover the upper surfaces of the sub-semiconductor package 1000 and the third semiconductor chip 400. In other example embodiments, the package molding layer 900 may not cover the upper surfaces of the sub-semiconductor package 1000 and the third semiconductor chip 400. For example, a heat dissipation member may be attached to the sub-semiconductor package 1000 and the third semiconductor chip 400 with a thermal interface material (TIM) layer therebetween.

A plurality of board connection terminals 540 may be attached to the plurality of first lower pads 524. The plurality of board connection terminals 540 may electrically connect the interposer 500 to a main board 600.

The main board 600 may include a base board layer 610, a plurality of second upper pads 622 and a plurality of second lower pads 624 respectively disposed on the upper surface and lower surface of the base board layer 610, and a plurality of second interconnect paths 630 that electrically connect the plurality of second upper pads 622 to the plurality of second lower pads 624 through the base board layer 610.

In some example embodiments, the main board 600 may be a printed circuit board. For example, the main board 600 may be a multi-layer printed circuit board. The base board layer 610 may include at least one material selected from phenol resin, epoxy resin, and polyimide.

A solder resist layer (not shown) exposing the plurality of second upper pads 622 and the plurality of second lower pads 624 may be formed on each of the upper surface and lower surface of the base board layer 610. The plurality of board connection terminals 540 may be connected to the plurality of second upper pads 622, and a plurality of external connection terminals 640 may be connected to the plurality of second lower pads 624. The plurality of board connection terminals 540 may electrically connect the plurality of first lower pads 524 to the plurality of second upper pads 622. The plurality of external connection terminals 640 connected to the plurality of second lower pads 624 may electrically and physically connect the semiconductor package 2000 to an external device.

In example embodiments, the semiconductor package 2000 may not include the main board 600, and the plurality of board connection terminals 540 of the interposer 500 may function as external connection terminals.

While the inventive concepts have been particularly shown and described with reference to embodiments thereof, it will be understood that various changes in form and details may be made therein without departing from the spirit and scope of the following claims.

1. A semiconductor chip comprising:
a semiconductor substrate having a first surface and a second surface over and opposite to the first surface;
an interconnect structure over the second surface of the semiconductor substrate;
a plurality of conductive patterns spaced apart from the semiconductor substrate with the interconnect structure therebetween, the plurality of conductive patterns connected to the interconnect structure;
a compensation pattern over the interconnect structure such that the compensation pattern is spaced apart from the plurality of conductive patterns in a horizontal direction and such that a distance from the compensation pattern to the second surface of the semiconductor substrate is greater than a distance from the plurality of conductive patterns to the second surface of the semiconductor substrate; and
an insulating spacer between the plurality of conductive patterns and the compensation pattern.

2. The semiconductor chip of claim 1, wherein the insulating spacer further includes a portion between the compensation pattern and the interconnect structure.

3. The semiconductor chip of claim 1, further comprising:
a frontside dielectric layer covering the plurality of conductive patterns, the compensation pattern, and the insulating spacer; and
a plurality of frontside bonding pads passing through the frontside dielectric layer and respectively contacting the plurality of conductive patterns.

4. The semiconductor chip of claim 3, wherein
the plurality of conductive patterns each include a first surface facing the semiconductor substrate and a second surface facing away from the semiconductor substrate, and the compensation pattern includes a first surface facing the semiconductor substrate and a second surface facing away from the semiconductor substrate, and
wherein the second surface of each of the plurality of conductive patterns is spaced apart from the frontside dielectric layer with a portion of the insulating spacer therebetween, and the first surface of the compensation pattern is in contact with another portion of the insulating spacer.

5. The semiconductor chip of claim 3, wherein a sidewall of the compensation pattern includes a portion facing the plurality of frontside bonding pads with the insulating spacer therebetween.

6. The semiconductor chip of claim 1, wherein
the plurality of conductive patterns each include a first surface facing the semiconductor substrate and a second surface facing away from the semiconductor substrate, and the compensation pattern includes a first surface facing the semiconductor substrate and a second surface facing away from the semiconductor substrate, and
wherein the second surface of each of the plurality of conductive patterns and the second surface of the compensation pattern are on a same plane.

7. The semiconductor chip of claim 1, wherein the plurality of conductive patterns each include a first surface facing the semiconductor substrate and a second surface facing away from the semiconductor substrate, and the compensation pattern includes a first surface facing the semiconductor substrate and a second surface facing away from the semiconductor substrate, and
wherein the insulating spacer includes
a first spacer layer over the interconnect structure, the first spacer layer covering the second surface of each of the plurality of conductive patterns and a sidewall of each of the plurality of conductive patterns; and
a second spacer layer on the first spacer layer, the second spacer layer covering the first surface and a sidewall of the compensation pattern.

8. The semiconductor chip of claim 7, further comprising:
a frontside dielectric layer covering the plurality of conductive patterns, the compensation pattern, and the insulating spacer; and
a plurality of frontside bonding pads passing through the frontside dielectric layer and respectively contacting the second surfaces of the plurality of conductive patterns,
wherein the second surface of each of the plurality of conductive patterns is spaced apart from the frontside dielectric layer with the first spacer layer therebetween, and the sidewall of each of the plurality of conductive patterns is spaced apart from the sidewall of the compensation pattern with the first spacer layer and the second spacer layer therebetween.

9. The semiconductor chip of claim 1, further comprising:
a frontside dielectric layer covering the plurality of conductive patterns, the compensation pattern, and the insulating spacer;
a plurality of frontside bonding pads passing through the frontside dielectric layer and respectively contacting the plurality of conductive patterns; and
at least one first frontside dummy pad passing through the frontside dielectric layer and contacting the compensation pattern.

10. The semiconductor chip of claim 1, further comprising:
a dummy pattern on the interconnect structure and between a first conductive pattern of the plurality of conductive patterns and a second conductive pattern of the plurality of conductive patterns,
wherein the compensation pattern includes a first portion between the first conductive pattern and the dummy pattern and a second portion between the second conductive pattern and the dummy pattern, and the insulating spacer separates the compensation pattern, the first conductive pattern, the second conductive pattern, and the dummy pattern from each other.

11. A semiconductor chip comprising:
a semiconductor substrate;
an interconnect structure on an upper surface of the semiconductor substrate, the interconnect structure including a plurality of interconnection lines, a plurality of interconnection vias, and an interconnect insulating layer surrounding the plurality of interconnection lines and the plurality of interconnection vias;
a plurality of conductive patterns over the interconnect structure, the plurality of conductive patterns spaced apart from each other in a horizontal direction and having thicknesses that are greater than those of the plurality of interconnect lines in a vertical direction;
a compensation pattern over the interconnect structure, the compensation pattern spaced apart from the plurality of conductive patterns in the horizontal direction;
an insulating spacer between the compensation pattern and the plurality of conductive patterns and between the interconnect structure and the compensation pattern;
a frontside dielectric layer covering the plurality of conductive patterns, the compensation pattern, and the insulating spacer; and
a plurality of frontside bonding pads passing through the frontside dielectric layer and the insulating spacer and respectively contacting the plurality of conductive patterns.

12. The semiconductor chip of claim 11, wherein a lower surface of the compensation pattern is at a lower vertical level than an upper surface of each of the plurality of conductive patterns.

13. The semiconductor chip of claim 11, wherein, in a plan view, the compensation pattern surrounds the plurality of conductive patterns.

14. The semiconductor chip of claim 11, wherein the plurality of conductive patterns include a first conductive pattern and a second conductive pattern adjacent to each other with the compensation pattern therebetween,
wherein, in a plan view, a first distance between the first conductive pattern and the compensation pattern is equal to a second distance between the second conductive pattern and the compensation pattern.

15. The semiconductor chip of claim 11, wherein, in a plan view, the compensation pattern has a plurality of holes,
wherein the plurality of conductive patterns are respectively within the plurality of holes such that each of the plurality of conductive patterns has an independent island shape.

16. The semiconductor chip of claim 11, wherein, in a plan view, the compensation pattern has a hole accommodating the plurality of conductive patterns,
where the plurality of conductive patterns include
a first conductive pattern; and
a first group of conductive patterns surrounding the first conductive pattern in a plan view such that at least a portion of the first group of conductive patterns have sidewalls facing the compensation pattern,
wherein the first group of conductive patterns are each spaced apart from the compensation pattern by a first separation distance, and a distance between the first conductive pattern and at least one of the first group of conductive patterns is less than twice the first separation distance.

17. The semiconductor chip of claim 11, further comprising:
a dummy pattern over the interconnect structure, the dummy pattern between a first conductive pattern of the plurality of conductive patterns and a second conductive pattern of the plurality of conductive patterns,
wherein, in a plan view, the first conductive pattern, the second conductive pattern, and the dummy pattern are disposed within a hole in the compensation pattern, the first conductive pattern, the second conductive pattern, and the dummy pattern are each spaced apart from the compensation pattern by a first separation distance, and a first distance between the first conductive pattern and the dummy pattern and a second distance between the second conductive pattern and the dummy pattern are each less than twice the first separation distance.

18. A semiconductor package comprising:
a first semiconductor chip; and
a second semiconductor chip bonded to the first semiconductor chip,
wherein the first semiconductor chip comprises
a first semiconductor substrate including a first surface and a second surface opposite to each other,
a plurality of first backside bonding pads on the first surface of the first semiconductor substrate, and
a first backside dielectric layer surrounding a sidewall of each of the plurality of first backside bonding pads on the first surface of the first semiconductor substrate,
wherein the second semiconductor chip comprises
a second semiconductor substrate including a first surface facing away from the semiconductor substrate and a second surface facing the first surface of the first semiconductor substrate,
an interconnect structure on the second surface of the second semiconductor substrate,
a frontside interconnect layer spaced apart from the second semiconductor substrate with the interconnect structure therebetween,
a second frontside dielectric layer between the frontside interconnect layer and the first backside dielectric layer of the first semiconductor chip, such the second frontside dielectric layer of the second semiconductor chip is bonded to the first backside dielectric layer of the first semiconductor chip, and
a plurality of second frontside bonding pads passing through the second frontside dielectric layer such that the plurality of second frontside bonding pads are bonded to the plurality of first backside bonding pads,
wherein the frontside interconnect layer includes
a plurality of conductive patterns spaced apart from each other in a horizontal direction and each including a first surface in contact with the interconnect structure and a second surface opposite to the first surface,
a compensation pattern spaced apart from the plurality of conductive patterns in the horizontal direction and including a first surface facing the interconnect structure and a second surface opposite to the first surface, the second surface in contact with the second frontside dielectric layer, the compensation pattern being, and
an insulating spacer between the plurality of conductive patterns and the compensation pattern and in contact with the second surface of each of the plurality of conductive patterns and the first surface of the compensation pattern, and
wherein the plurality of second frontside bonding pads pass through the insulating spacer and contact the second surface of each of the plurality of conductive patterns.

19. The semiconductor package of claim 18, wherein a sidewall of the compensation pattern includes a portion facing the plurality of second frontside bonding pads with the insulating spacer therebetween.

20. The semiconductor package of claim 18, wherein the insulating spacer includes
a first spacer layer on the interconnect structure and covering the second surface and a sidewall of each of the plurality of conductive patterns; and
a second spacer layer spaced apart from the plurality of conductive patterns with the first spacer therebetween and covering the first surface and a sidewall of the compensation pattern, and
wherein the second surface of each of the plurality of conductive patterns is spaced apart from the second frontside dielectric layer with the first spacer layer therebetween, and the sidewall of each of the plurality of conductive patterns is spaced apart from the sidewall of the compensation pattern with the first spacer layer and the second spacer layer therebetween.

21.-27. (canceled)
